(19) United States
(12) Patent Application Publication
(10) Pub. No.: US 2026/0314178 A1
(43) Pub. Date: Oct. 8, 2026

(54) DISPLAY DEVICE, ELECTRONIC DEVICE AND METHOD FOR MANUFACTURING DISPLAY DEVICE

(71) Applicant: Samsung Display Co., Ltd., Yongin-si, (KR)

(72) Inventors: Myeong Ho KIM, Yongin-si (KR); Ki Hwan KIM, Yongin-si (KR); Jun Hyung LIM, Yongin-si (KR)

(73) Assignee: Samsung Display Co., Ltd., Yongin-si (KR)

(21) Appl. No.: 19/416,658

(22) Filed: Dec. 11, 2025

(30) Foreign Application Priority Data
Apr. 4, 2025 (KR) 10-2025-0043789

(51) Int. Cl. H10K 59/121; H10D 86/01; H10D 86/40; H10D 86/60; H10K 59/12; H10K 59/131; H10K 102/00

(52) U.S. Cl. CPC H10K 59/1213; H10D 86/0223; H10D 86/423; H10D 86/441; H10D 86/481; H10D 86/60; H10K 59/1201; H10K 59/131; H10K 2102/351

(57) ABSTRACT

A display device according to an embodiment may include a substrate, a pixel on the substrate, and a driving circuit on the substrate. The pixel may include a driving transistor and a first switching transistor. The driving transistor may include a first active layer. The first active layer may include a second oxide semiconductor layer on a first oxide semiconductor layer. The first oxide semiconductor layer may include a first oxide semiconductor. The second oxide semiconductor layer may include a second oxide semiconductor. The first switching transistor may include a second active layer including the second oxide semiconductor. The driving circuit may include a buffer transistor. The buffer transistor may include a third active layer including the first oxide semiconductor. The first oxide semiconductor may include a crystalline oxide semiconductor.

### CROSS-REFERENCE TO RELATED APPLICATION

This application claims priority from Korean Patent Application No. 10-2025-0043789 filed on Apr. 4, 2025, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device and an electronic device capable of displaying an image, and a method for manufacturing the display device.

### 2. Description of the Related Art

As the information society develops, the demand for display devices and electronic devices capable of displaying images has increased and diversified. Accordingly, various types of display devices and electronic devices including pixels for displaying images have been developed. The display device may be provided alone or may be included in an electronic device and used as a display screen of the electronic device.

### SUMMARY

Aspects of the present disclosure provide a display device and an electronic device capable of improving image quality, improving power consumption, and reducing a non-display area, and a method for manufacturing the display device.

However, aspects of the present disclosure are not restricted to those set forth herein. The above and other aspects of the present disclosure will become more apparent to one of ordinary skill in the art to which the present disclosure pertains by referring to the detailed description of the present disclosure given below.

According to an aspect of the present disclosure, a display device may include a substrate; a pixel on the substrate, the pixel including a driving transistor and a first switching transistor, the driving transistor including a first active layer, the first active layer including a first oxide semiconductor layer and a second oxide semiconductor layer on the first oxide semiconductor layer, the first oxide semiconductor layer including a first oxide semiconductor, the second oxide semiconductor layer including a second oxide semiconductor, and the first switching transistor including a second active layer including the second oxide semiconductor; and a driving circuit on the substrate and including a buffer transistor, the buffer transistor including a third active layer including the first oxide semiconductor, wherein the first oxide semiconductor may include a crystalline oxide semiconductor.

In an embodiment, the pixel may further include a second switching transistor. The second switching transistor may be electrically connected between a first power line and the driving transistor. The first power line may be configured to have a first driving voltage applied thereto. The second switching transistor may include a fourth active layer, and the fourth active layer may include the first oxide semiconductor.

In an embodiment, the driving circuit may further include a control circuit. In response to an input signal, the control circuit may be configured to control a voltage level of a node connected to a gate electrode of the buffer transistor. The control circuit may include a control transistor. The control transistor may include a fifth active layer, and the fifth active layer may include the second oxide semiconductor.

In an embodiment, a mobility of the first oxide semiconductor may be higher than a mobility of the second oxide semiconductor.

In an embodiment, the second oxide semiconductor may include an amorphous oxide semiconductor.

In an embodiment, the first oxide semiconductor may include crystalline indium gallium oxide, and the second oxide semiconductor may include amorphous indium gallium zinc oxide.

In an embodiment, a thickness of the first oxide semiconductor layer may be ⅓ to ½ of a thickness of the first active layer.

In an embodiment, a thickness of the first oxide semiconductor layer may be 100 Å to 150 Å, and a thickness of the second oxide semiconductor layer may be 150 Å to 200 Å.

In an embodiment, the display device may further include a first gate insulating layer on the first active layer, the second active layer, and the third active layer. A gate electrode of the first switching transistor may be on the first gate insulating layer and may overlap a portion of the second active layer.

In an embodiment, the display device may further include a second gate insulating layer on the first gate insulating layer and the gate electrode of the first switching transistor. A gate electrode of the driving transistor may be on the second gate insulating layer and may overlap a portion of the first active layer.

In an embodiment, the display device may further include a capacitor electrode between the first gate insulating layer and the second gate insulating layer.

In an embodiment, a gate electrode of the driving transistor may be on the first gate insulating layer and may overlap a portion of the first active layer.

In an embodiment, the display device may further include a second gate insulating layer on the gate electrode of the first switching transistor, the gate electrode of the driving transistor, and the first gate insulating layer; and a capacitor electrode on the second gate insulating layer.

In an embodiment, a gate electrode of the buffer transistor may be on the first gate insulating layer and may overlap a portion of the third active layer.

According to an aspect of the present disclosure, an electronic device may include a display module including a display panel; and a processor configured to transmit an image data signal to the display module. The display panel may include a substrate, a pixel on the substrate, and a driving circuit on the substrate. The pixel may include a driving transistor and a first switching transistor. The driving transistor may include a first active layer. The first active layer may include a first oxide semiconductor layer and a second oxide semiconductor layer on the first oxide semiconductor layer. The first oxide semiconductor layer may include a first oxide semiconductor. The second oxide semiconductor layer may include a second oxide semiconductor. The first switching transistor may include a second active layer including the second oxide semiconductor. The driving circuit may include a buffer transistor. The buffer transistor may include a third active layer including the first oxide semiconductor. The first oxide semiconductor may include a crystalline oxide semiconductor.

In an embodiment, the pixel may further include a second switching transistor. The second switching transistor may be electrically connected between a first power line and the driving transistor. The first power line may be configured to have a first driving voltage applied thereto. The second switching transistor may include a fourth active layer. The fourth active layer may include the first oxide semiconductor.

In an embodiment, the driving circuit may further include a control circuit. In response to an input signal, the control circuit may be configured to control a voltage level of a node connected to a gate electrode of the buffer transistor. The control circuit may include a control transistor. The control transistor may include a fifth active layer. The fifth active layer may include the second oxide semiconductor.

According to an aspect of the present disclosure, a method for manufacturing a display device may include forming a first oxide semiconductor layer on a substrate; forming a second oxide semiconductor layer on the first oxide semiconductor layer to form a first active layer including the first oxide semiconductor layer and the second oxide semiconductor layer; forming a first gate insulating layer on the substrate and the first active layer; and forming a gate electrode of a driving transistor on the first gate insulating layer. The driving transistor may include the first active layer. The gate electrode of the driving transistor may overlap the first active layer. The forming the first oxide semiconductor layer may include forming a first semiconductor pattern on the substrate and crystallizing the first semiconductor pattern. The first semiconductor pattern may include an amorphous oxide semiconductor.

In an embodiment, in the forming the first oxide semiconductor layer, a third active layer including a same material as the first oxide semiconductor layer may be further formed. In the forming the second oxide semiconductor layer, a second active layer including a same material as the second oxide semiconductor layer may be further formed.

In an embodiment, the method may further include forming a switching transistor and a buffer transistor by forming a gate electrode of the switching transistor and a gate electrode of the buffer transistor on the first gate insulating layer. The switching transistor may include the second active layer and the gate electrode of the switching transistor may be formed above the second active layer so as to overlap the second active layer. The buffer transistor may include the third active layer and the gate electrode of the buffer transistor may be formed above the third active layer so as to overlap the third active layer.

With a display device and an electronic device, and a method for manufacturing the display device according to embodiments, materials and structures of active layers included in pixel transistors and driver transistors may be differentiated or optimized according to operation characteristics required for each pixel transistor and each driver transistor. Accordingly, image quality of the display device and the electronic device may be improved, power consumption may be reduced, and a non-display area may be reduced.

However, effects according to the embodiments of the present disclosure are not limited to those examples above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view illustrating a display device according to an embodiment;

FIG. 2 is a plan view illustrating a display panel of FIG. 1;

FIG. 3 is an equivalent circuit diagram illustrating a pixel according to an embodiment;

FIG. 4 is a schematic diagram illustrating a first driving circuit according to an embodiment;

FIG. 5 is a schematic diagram illustrating a stage of the first driving circuit according to an embodiment;

FIG. 6 is a cross-sectional view illustrating a portion of the display panel according to an embodiment;

FIGS. 7 and 8 are graphs illustrating a change in characteristics of a driving transistor according to thicknesses of a first oxide semiconductor layer and a second oxide semiconductor layer;

FIG. 9 is a cross-sectional view illustrating a portion of a display panel according to an embodiment;

FIG. 10 is a cross-sectional view illustrating a portion of a display panel according to an embodiment;

FIG. 11 is a cross-sectional view illustrating a portion of a display panel according to an embodiment;

FIG. 12 is a cross-sectional view illustrating a portion of a display panel according to an embodiment;

FIGS. 13 to 20 are cross-sectional views illustrating a method for manufacturing the display device according to an embodiment;

FIG. 21 is a block diagram of an electronic device according to an embodiment; and

FIG. 22 is schematic views of electronic devices according to various embodiments.

### DETAILED DESCRIPTION OF THE EMBODIMENTS

Inventive concepts will now be described more fully hereinafter with reference to the accompanying drawings, in which example embodiments of inventive concepts are shown. Inventive concepts may, however, be embodied in different forms and should not be construed as limited to the embodiments set forth herein. Rather, these embodiments are provided so that this disclosure will be thorough and complete, and will filly convey the scope of inventive concepts to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Features of each of various embodiments of the present disclosure may be partially or entirely combined with each other and may interwork technically with each other, and respective embodiments may be implemented independently of each other or may be implemented together in association with each other.

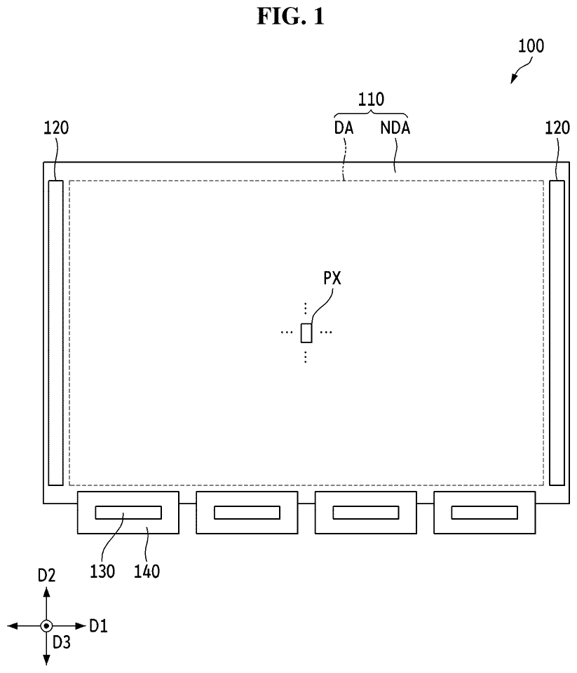

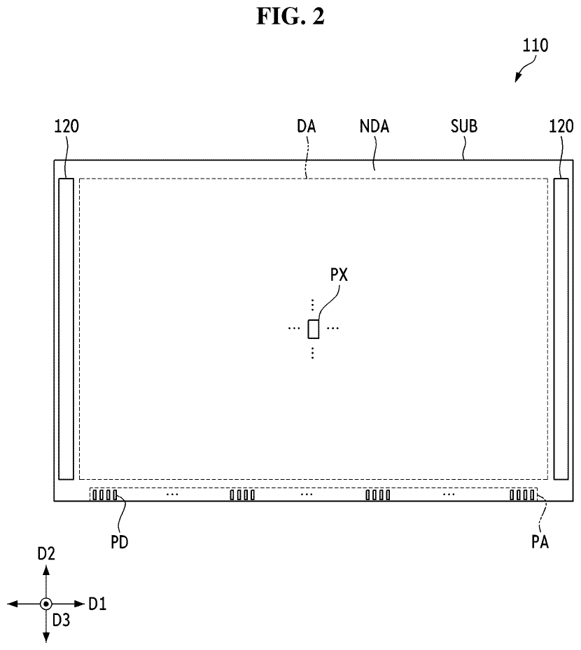

FIG. 1 is a plan view illustrating a display device according to an embodiment. FIG. 2 is a plan view illustrating a display panel of FIG. 1.

Referring to FIGS. 1 and 2, a display device 100 is a device that displays a moving image or a still image, and may be included in various electronic devices such as televisions, laptop computers, monitors, billboards, and the Internet of Things (IOT) as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs) and used as a display screen of various electronic devices. In addition, the display device 100 may also be included in other electronic devices such as a virtual reality (VR) device or an augmented reality (AR) device and used to display images in other electronic devices. In an embodiment, an electronic device including the display device 100 may further include a display device housing portion in which the display device 100 is housed and/or a case or a cover for protecting the display device 100.

In an embodiment, the display device 100 may be a light emitting display device such as an organic light emitting display device including organic light emitting diodes, a quantum dot light emitting display device including quantum dot light emitting layers, an inorganic light emitting display device including inorganic semiconductors, or a micro light emitting display device including micro light emitting diodes such as micro or nano light emitting diodes (micro LEDs or nano LEDs), but is not limited thereto. For example, the display device 100 may also be a type of display device other than the light emitting display device. Hereinafter, embodiments in which the display device 100 is a light emitting display device (e.g., an organic light emitting display device) will be disclosed.

The display device 100 may include a display panel 110 including pixels PX, and a first driving circuit 120 and a second driving circuit 130 supplying driving signals to the pixels PX. The display device 100 may further include additional components. For example, the display device 100 may further include a power supply unit for supplying driving voltages to the pixels PX, the first driving circuit 120, and the second driving circuit 130, a timing controller for controlling operations of the first driving circuit 120 and the second driving circuit 130, and the like.

The display panel 110 may include a display area DA and a non-display area NDA. The display area DA is an area where the pixels PX are disposed, and may be an area where an image is displayed by the pixels PX. The non-display area NDA is an area other than the display area DA, and an image may not be displayed in the non-display area NDA. In an embodiment, the non-display area NDA may be located around the display area DA, and may surround the display area DA.

In FIGS. 1 and 2, a first direction D1, a second direction D2, and a third direction D3 are defined. In an embodiment, the first direction D1 may be a transverse direction of the display panel 110, and the second direction D2 may be a longitudinal direction of the display panel 110. The third direction D3 may be a thickness direction of the display panel 110.

In an embodiment, the display panel 110 may have a rectangular shape in plan view. It has been illustrated in FIGS. 1 and 2 that the display panel 110 has a shape in which a transverse length is greater than a longitudinal length, but a shape of the display panel 110 is not limited thereto. For example, the display panel 110 may have a shape in which the longitudinal length is greater than the transverse length or have a square shape, or the like. The display panel 110 may include angled corners or rounded corners. The display panel 110 is not limited to having the rectangular shape as illustrated in FIGS. 1 and 2 in plan view, and may have a non-rectangular polygonal shape, a circular shape, an elliptical shape, an irregular shape, or other shapes in plan view.

The display panel 110 may have rigid or flexible characteristics. The display panel 110 may be provided in the display device 100 in a state in which it is not bent or provided in the display device 100 in a state in which it is bent in a partial section.

The display panel 110 may include a substrate SUB and pixels PX disposed on the substrate SUB. The pixels PX may be disposed in a display area DA on the substrate SUB.

The substrate SUB may be a base member of the display panel 110. The substrate SUB may include a display area DA and a non-display area NDA disposed around the display area DA.

The display area DA may have various shapes according to embodiments. For example, the display area DA may have a rectangular shape, a non-rectangular polygonal shape, a circular shape, an elliptical shape, an irregular shape, or other shapes. In an embodiment, the display area DA may have a shape matching the shape of the display panel 110.

The pixels PX may be arranged in the display area DA. For example, the display area DA may include pixel areas where the respective pixels PX are disposed.

In an embodiment, the display device 100 may be a light emitting display device, and the pixel PX may include a light emitting element located in each emission area and a pixel circuit connected to the light emitting element. In describing embodiments, the term “connection” may include the meaning of an electrical connection and/or a physical connection. Each pixel circuit may include a plurality of pixel transistors and at least one capacitor.

The non-display area NDA may include a pad area PA where pads PD are disposed. In an embodiment, the non-display area NDA may further include a driving circuit area located on at least one side of the display area DA. At least one driver, the pads PD, lines, and the like, may be disposed in the non-display area NDA.

At least one driver for driving the pixels PX or a portion of the driver may be disposed in the driving circuit area. As an example, circuit elements constituting the first driving circuit 120 (e.g., driver transistors and driver capacitors constituting stages of the first driving circuit 120) may be disposed in the driving circuit area on the substrate SUB. In an embodiment, the circuit elements of the first driving circuit 120 may be formed inside the display panel 110 together with the pixels PX.

In an embodiment, the driver transistors included in the first driving circuit 120 may be formed simultaneously with the pixel transistors included in the pixels PX. In this case, the driver transistors may include a material included in the pixel transistors.

The pads PD may be disposed in the pad area PA. At least one circuit board 140 may be disposed on and/or bonded onto the pads PD. In an embodiment, a plurality of circuit boards 140 may be disposed on the pads PD. The pads PD may include signal pads and power pads for transmitting driving signals and driving voltages required for driving the pixels PX and/or the first driving circuit 120 to the inside of the display panel 110.

The first driving circuit 120 and the second driving circuit 130 may generate driving signals for controlling operation timing, luminance, and the like, of the pixels PX, and supply the driving signals to the pixels PX. For example, the first driving circuit 120 may be a gate driver including a scan driver, and may be connected to the pixels PX through respective gate lines. The first driving circuit 120 may supply respective gate signals (e.g., gate signals for controlling driving timing of the pixels PX, including scan signals) to the pixels PX. The second driving 130 circuits may be a data driver including source driving circuits, and may be connected to the pixels PX through respective data lines. The second driving circuit 130 may supply respective data signals to the pixels PX.

In an embodiment, at least one of the first driving circuit 120 and the second driving circuit 130 may be embedded in the display panel 110. For example, the first driving circuit 120 may be disposed on the substrate SUB of the display panel 110, and may be disposed and/or formed in the non-display area NDA. As an example, the first driving circuits 120 may be disposed in portions of the non-display area NDA located on opposite sides of the display area DA (e.g., the left side and the right side of the display area DA).

In an embodiment, the second driving circuit 130 may be disposed or formed outside the display panel 110 and electrically connected to the display panel 110. For example, the second driving circuits 130 may be implemented as a plurality of integrated circuit chips and disposed on the circuit boards 140 electrically connected to the pixels PX of the display panel 110. Alternatively, the second driving circuit 130 may be implemented as at least one integrated circuit chip and mounted on the non-display area NDA of the display panel 110.

The circuit board 140 may be connected to the display panel 110 through the pads PD. The circuit board 140 may be a flexible printed circuit board (FPCB), a printed circuit board (PCB), or a flexible film such as a chip on film (COF), but is not limited thereto. In an embodiment, the circuit board 140 may be connected to the timing controller, the power supply unit, and the like, through another circuit board, a connector, or the like.

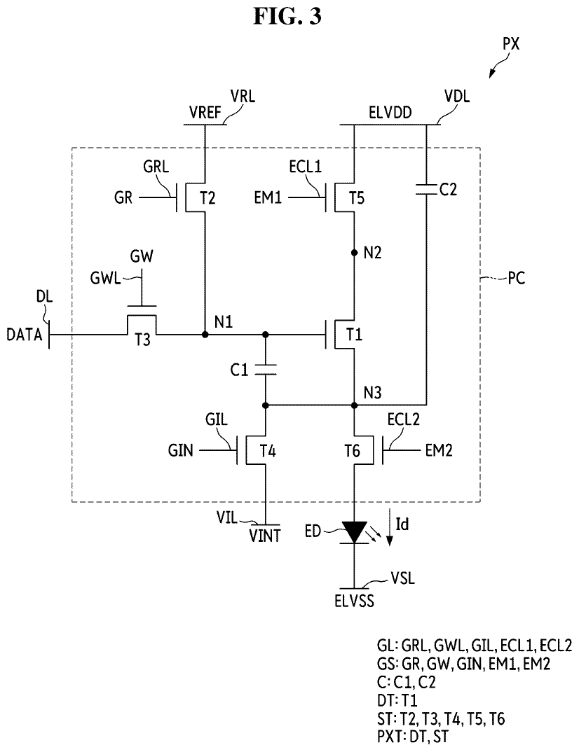

FIG. 3 is an equivalent circuit diagram illustrating a pixel according to an embodiment. For example, FIG. 3 illustrates a pixel PX of a light emitting display device including a light emitting element ED. A type and/or a structure of the pixel PX that may be included in the display device 100 may be variously changed according to embodiments.

Referring to FIG. 3, the pixel PX may include a light emitting element ED and a pixel circuit PC electrically connected to the light emitting element ED. The light emitting element ED is a light source of the pixel PX and may be, for example, an organic light emitting diode, but is not limited thereto. The pixel circuit PC may control light emission of the light emitting element ED.

The pixel circuit PC may supply a driving current Id to the light emitting element ED in response to the driving signals supplied from the first driving circuit 120 and the second driving circuit 130. For example, the pixel circuit PC may supply the driving current Id to the light emitting element ED in response to respective gate signals GS supplied from the first driving circuit 120 through respective gate lines GL and a data signal DATA supplied from the second driving circuit 130 through a data line DL.

In an embodiment, the pixel PX may be electrically connected to a first gate line GWL transmitting a first gate signal GW (e.g., a scan signal), a second gate line GIL transmitting a second gate signal GIN, a third gate line GRL transmitting a third gate signal GR, a first emission control line ECL1 transmitting a first emission control signal EM1, a second emission control line ECL2 transmitting a second emission control signal EM2, and the data line DL transmitting the data signal DATA. In addition, the pixel PX may be further connected to a first power line VDL transmitting a first driving voltage ELVDD (e.g., a high-potential first pixel voltage or anode voltage), a second power line VSL transmitting a second driving voltage ELVSS (e.g., a low-potential second pixel voltage or cathode voltage), an initialization power line VIL transmitting an initialization voltage VINT, and a reference power line VRL transmitting a reference voltage VREF. Types and the numbers of signal lines and power lines connected to the pixel PX may be changed depending on a structure, an operation method, and the like, of the pixel PX.

The pixel circuit PC may include pixel transistors PXT and at least one capacitor C. The pixel transistors PXT may include a driving transistor DT and at least one switching transistor ST.

In an embodiment, the pixel circuit PC may include a first transistor T1 as the driving transistor DT of the pixel PX, and may include a second transistor T2, a third transistor T3, a fourth transistor T4, a fifth transistor T5, and a sixth transistor T6 as the switching transistors ST of the pixel PX. In an embodiment, the pixel circuit PC may include a plurality of capacitors C. For example, the pixel circuit PC may include a first capacitor C1 and a second capacitor C2. However, a structure of the pixel circuit PC is not limited to that of an embodiment illustrated in FIG. 3, and a structure, an input signal, and/or an operation method of the pixel circuit PC may be variously changed according to embodiments.

The first transistor T1 may control a magnitude of the driving current Id supplied to the light emitting element ED according to its gate-source voltage. The switching transistors ST may be turned on or off according to their respective gate-source voltages. Depending on a type (e.g., a P-type or N-type transistor) and/or an operation condition of each of the pixel transistors PXT, a first electrode of each of the pixel transistors PXT may be a drain electrode (or a drain region) or a source electrode (or a source region), and a second electrode of each of the pixel transistors PXT may be an electrode different from the first electrode. For example, when the first electrode is the drain electrode, the second electrode may be the source electrode. In an embodiment, all of the pixel transistors PXT may be N-type transistors, but embodiments are not limited thereto.

In an embodiment, the pixel transistors PXT may be oxide transistors including at least one oxide semiconductor. For example, an active layer of each of the pixel transistors PXT may include at least one oxide semiconductor. However, embodiments are not limited thereto. For example, at least one pixel transistor PXT may also be made of a semiconductor material (e.g., amorphous silicon or polysilicon) other than the oxide semiconductor.

In an embodiment, all of the pixel transistors PXT disposed in the display panel 110, including the pixel transistors PXT included in each pixel PX, may be oxide transistors including oxide semiconductors. The oxide semiconductor has high carrier mobility and a low leakage current, and accordingly, a great voltage drop may not occur even though a driving time of the oxide transistor is long. When the pixel transistors PXT are formed as the oxide transistors, a leakage current of the pixel PX may be reduced or prevented, and power consumption of the display device 100 may be reduced.

The first transistor T1 may include a gate electrode electrically connected to a first node N1, a first electrode (e.g., a drain electrode or a drain region) electrically connected to a second node N2, and a second electrode (e.g., a source electrode or a source region) electrically connected to a third node N3. The first electrode of the first transistor T1 may be electrically connected to the first power line VDL via the fifth transistor T5, and the second electrode may be electrically connected to the light emitting element ED via the sixth transistor T6. The first transistor T1 may control the driving current Id flowing to the light emitting element ED in response to the data signal DATA transmitted to the first node N1.

The second transistor T2 may include a gate electrode electrically connected to the third gate line GRL, a first electrode electrically connected to the reference power line VRL, and a second electrode electrically connected to the first node N1. The second transistor T2 may be turned on by the third gate signal GR transmitted to the third gate line GRL to transmit the reference voltage VREF transmitted to the reference power line VRL to the first node N1.

The third transistor T3 may include a gate electrode electrically connected to the first gate line GWL, a first electrode electrically connected to the data line DL, and a second electrode electrically connected to the first node N1. The third transistor T3 may be turned on by the first gate signal GW (e.g., the first gate signal GW of a gate-on voltage corresponding to a high level) transmitted to the first gate line GWL to electrically connect the data line DL and the first node N1 to each other. Accordingly, the data signal DATA transmitted to the data line DL may be transmitted to the first node N1.

The fourth transistor T4 may include a gate electrode electrically connected to the second gate line GIL, a first electrode electrically connected to the third node N3, and a second electrode electrically connected to the initialization power line VIL. The fourth transistor T4 may be turned on by the second gate signal GIN transmitted to the second gate line GIL to transmit the initialization voltage VINT transmitted to the initialization power line VIL to the third node N3.

The fifth transistor T5 may include a gate electrode electrically connected to the first emission control line ECL1, a first electrode electrically connected to the first power line VDL, and a second electrode electrically connected to the second node (or the first electrode of the first transistor T1). The fifth transistor T5 may be turned on by the first emission control signal EM1 transmitted to the first emission control line ECL1 to electrically connect the first power line VDL and the first transistor T1 to each other.

The sixth transistor T6 may include a gate electrode electrically connected to the second light emitting control line ECL2, a first electrode electrically connected to the third node N3, and a second electrode electrically connected to the light emitting element ED. The sixth transistor T6 may be turned on by the second light emitting control signal EM2 transmitted to the second light emitting control line ECL2 to electrically connect the first transistor T1 and the light emitting element ED to each other.

In an embodiment, the first light emitting control signal EM1 and the second light emitting control signal EM2 may be signals of different waveforms that may be independently controlled. Accordingly, the driving of the fifth transistor T5 and the sixth transistor T6 may be independently controlled. As an example, even though the fifth transistor T5 is turned on by the first emission control signal EM1 of a gate-on voltage during a non-emission period of the pixel PX including a compensation period for uniformizing operation characteristics of the pixel PX, the sixth transistor T6 may be turned off by the second emission control signal EM2 of a gate-off voltage. Accordingly, a voltage fluctuation of the third node N3 due to the second driving voltage ELVSS or the like may be prevented. During an emission period of the pixel PX, both the fifth transistor T5 and the sixth transistor T6 may be turned on by the first emission control signal EM1 and the second emission control signal EM2 of gate-on voltages. Accordingly, the driving current Id may flow in the pixel PX.

The first capacitor C1 may be electrically connected between the first node N1 and the third node N3. The first capacitor C1 may be a storage capacitor of the pixel PX, and may store a voltage corresponding to the data signal DATA (e.g., a data voltage).

The second capacitor C2 may be electrically connected between the first power line VDL and the third node N3. The second capacitor C2 may be a hold capacitor of the pixel PX, and may serve to stabilize and/or uniformize the operation characteristics of the pixel PX.

The light emitting element ED may be electrically connected between the sixth transistor T6 and the second power line VSL. For example, the light emitting element ED may include a first electrode (e.g., an anode electrode) electrically connected to the second electrode of the sixth transistor T6, a second electrode (e.g., a cathode electrode) facing the first electrode and connected to the second power line VSL, and a light emitting layer interposed between the first electrode and the second electrode. In an embodiment, the first electrode of the light emitting element ED may be a pixel electrode individually disposed in each pixel PX, and the second electrode of the light emitting element ED may be a common electrode shared by a plurality of pixels PX. The light emitting element ED may emit light with luminance corresponding to the driving current Id during a period in which the driving current Id flows in the pixel PX.

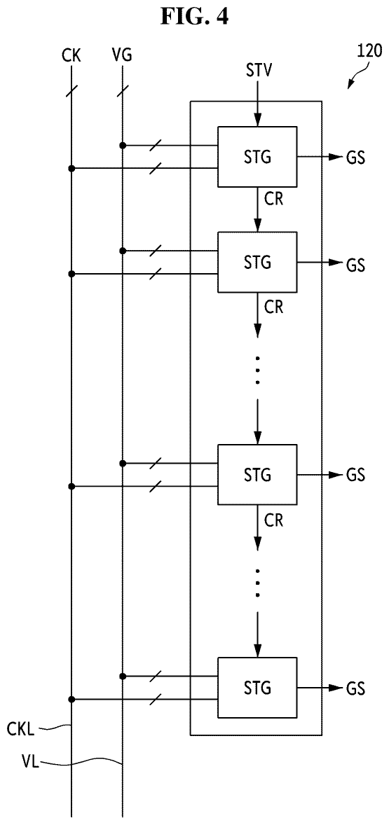

FIG. 4 is a schematic diagram illustrating a first driving circuit according to an embodiment. FIG. 4 schematically illustrates one gate signal generation unit sequentially outputting one type of gate signals GS (e.g., the first gate signals GW of FIG. 3) as a component that may be included in the first driving circuit 120. In an embodiment, when each pixel PX is driven by a plurality of gate signals GS, the first driving circuit 120 may include a plurality of gate signal generation units for outputting the plurality of gate signals GS.

Referring to FIG. 4 in addition to FIGS. 1 to 3, the first driving circuit 120 may include a plurality of stages STG sequentially outputting the gate signals GS. Each stage STG may receive at least one clock signal CK and at least one driving voltage VG from at least one clock line CKL and at least one voltage line VL, respectively. As an example, the stages STG may receive a plurality of clock signals CK (e.g., a plurality of clock signals CK having different waveforms and/or phases) and a plurality of driving voltages VG (e.g., a plurality of driving voltages VG including a gate-high voltage and a gate-low voltage) from a plurality of clock lines CKL and a plurality of voltage lines VL, respectively, and output the gate signals GS in response to the plurality of clock signals CK and the plurality of driving voltages VG. The stage STG may further output a carry signal CR to the previous stage STG and/or the subsequent stage STG.

In an embodiment, some and the others of the stages STG included in the first driving circuit 120 may be driven by different clock signals CK. As an example, at least one clock signal CK including a first clock signal may be input to some stages STG, and at least one other clock signal CK including a second clock signal different from the first clock signal may be input to the other stages STG.

In an embodiment, the plurality of stages STG may sequentially output the gate signals GS in response to a scan start signal such as a start pulse STV input from the outside. For example, a first stage STG may receive the start pulse STV through at least one signal line electrically connected to the timing controller, and output the gate signal GS and the carry signal CR using the start pulse STV. The other stages STG may output their respective gate signals GS and carry signals CR using the carry signals CR input from the previous stages STG.

Types, structures, the number, and the like, of stages STG included in the first driving circuit 120 may be variously changed according to embodiments. In addition, types, waveforms, the numbers, and the like, of input signals and output signals of the stages STG may be variously changed according to embodiments.

In an embodiment, the first driving circuit 120 may be formed inside the display panel 110 together with the pixels PX. For example, each of the stages STG may include driver transistors formed inside the display panel 110 together with the pixel transistors PXT of FIG. 3.

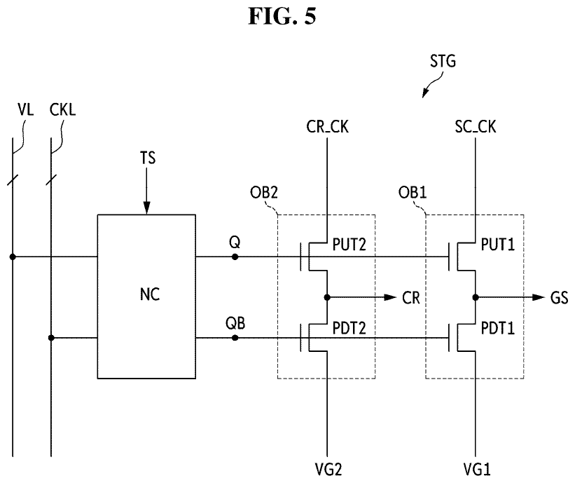

FIG. 5 is a schematic diagram illustrating a stage of the first driving circuit according to an embodiment. For example, FIG. 5 schematically illustrates any stage STG included in the first driving circuit 120.

Referring to FIG. 5, the stage STG may include a control circuit NC for controlling voltage levels of a first control node Q and a second control node QB, a first output circuit OB1 outputting the gate signal GS, and a second output circuit OB2 for outputting the carry signal CR.

The control circuit NC may be disposed at an input terminal of the stage STG and may receive an input signal TS (e.g., a timing control signal) including the start pulse STV or the carry signal CR. The control circuit NC may control the voltage levels of the first control node Q and the second control node QB in response to the input signal TS. The control circuit NC may include control transistors for controlling the voltage levels of the first control node Q and the second control node QB in response to the input signal TS. For example, the control circuit NC may be configured as a logic circuit including a plurality of control transistors. A structure or an operation method of the control circuit NC may be variously changed according to embodiments.

The first output circuit OB1 may include a first pull-up transistor PUT1 and a first pull-down transistor PDT1 that are electrically connected between a terminal to which a scan clock signal SC_CK is input and a terminal to which a first voltage VG1 (e.g., a first gate-low voltage of a first level) is input. The second output circuit OB2 may include a second pull-up transistor PUT2 and a second pull-down transistor PDT2 that are electrically connected between a terminal to which a carry clock signal CR_CK is input and a terminal to which a second voltage VG2 (e.g., a second gate-low voltage of a second level) is input. The first and second pull-up transistors PUT1 and PUT2 and the first and second pull-down transistors PDT1 and PDT2 may serve as output buffers that strengthen signals generated in the stage STG, and may also be referred to as “buffer transistors”.

A gate electrode of each of the first and second pull-up transistors PUT1 and PUT2 may be electrically connected to the first control node Q. The first and second pull-up transistors PUT1 and PUT2 may be turned on or off depending on the voltage level of the first control node Q. For example, the first and second pull-up transistors PUT1 and PUT2 may be turned on during a period in which a voltage of the first control node Q is a high-level voltage capable of turning on the first and second pull-up transistors PUT1 and PUT2.

A gate electrode of each of the first and second pull-down transistors PDT1 and PDT2 may be electrically connected to the second control node QB. The first and second pull-down transistors PDT1 and PDT2 may be turned on or off depending on the voltage level of the second control node QB. For example, the first and second pull-down transistors PDT1 and PDT2 may be turned on during a period in which a voltage of the second control node QB is a high-level voltage capable of turning on the first and second pull-down transistors PDT1 and PDT2.

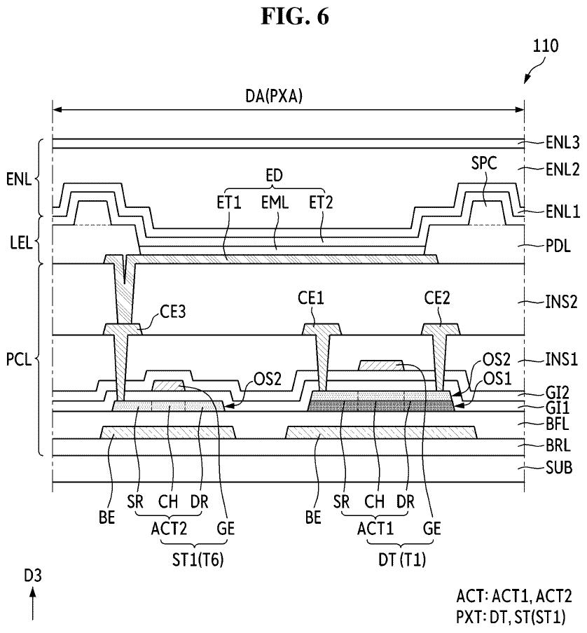

FIG. 6 is a cross-sectional view illustrating a portion of the display panel according to an embodiment. For example, FIG. 6 illustrates a portion of a pixel area PXA included in the display area DA of the display panel 110. FIG. 6 illustrate a light emitting display panel including a light emitting element ED (e.g., an organic light emitting diode) as an example of the display panel 110 to which embodiments may be applied.

Referring to FIG. 6 in addition to FIGS. 1 to 3, the display panel 110 may include a substrate SUB (or a base layer) and a panel circuit layer PCL, a light emitting element layer LEL, and an encapsulation layer ENL that are sequentially disposed on the substrate SUB.

In an embodiment, the display panel 110 may further include additional components provided above and/or below the encapsulation layer ENL. For example, the display panel 110 may further include at least one of a sensor layer (e.g., a touch sensor layer), an optical layer (e.g., a color filter layer and/or a wavelength conversion layer), and a protective layer (e.g., a protective film, an insulating layer, an upper substrate, and/or a window). Each of the sensor layer, the optical layer, and/or the protective layer may be provided above the encapsulation layer ENL or provided between the light emitting element layer LEL and the encapsulation layer ENL.

The substrate SUB may be a base member for forming the display panel 110, and may be a rigid or flexible substrate (or film). In an embodiment, the substrate SUB may be a substrate including an insulating material such as glass and having rigid characteristics, and may not be bent. Alternatively, the substrate SUB may be a flexible substrate including polyimide or other insulating materials and capable of being deformed, for example, bent, folded, or rolled, and may or may not be bent. A type and/or a material of the substrate SUB may be changed according to embodiments.

The panel circuit layer PCL (e.g., a pixel circuit layer or a thin film transistor layer) may be disposed on the substrate SUB. The panel circuit layer PCL may include circuit elements including the pixel transistors PXT and the capacitors C included in the pixels PX, and signal lines and power lines connected to the pixels PX.

FIG. 6 illustrates one driving transistor DT and one switching transistor ST disposed in any one pixel area PXA as an example of the circuit elements that may be included in the panel circuit layer PCL. For example, the driving transistor DT of FIG. 6 may be the first transistor T1 of FIG. 3, and the switching transistor ST of FIG. 6 may be one (e.g., the sixth transistor T6) of the switching transistors ST of FIG. 3.

In an embodiment, the driving transistor DT of the pixel PX may include a first active layer ACT1 of a multilayer (e.g., a double-layer) structure including a first oxide semiconductor layer OS1 and a second oxide semiconductor layer OS2. The “first active layer ACT1” may refer to an active layer ACT of the driving transistor DT. At least one of the switching transistors ST of the pixel PX may include a second active layer ACT2 of a single-layer structure including a second oxide semiconductor layer OS2. In describing embodiments, the switching transistor ST including the second oxide semiconductor layer OS2 is also referred to as a “first switching transistor ST1”. For example, at least one switching transistor ST including the sixth transistor T6 of FIG. 3 may be the first switching transistor ST1 including the second active layer ACT2 formed as the second oxide semiconductor layer OS2. The “second active layer ACT2” may refer to an active layer ACT of the first switching transistor ST1.

Each of the pixel transistors PXT may include an active layer ACT and a gate electrode GE overlapping a portion of the active layer ACT. For example, the driving transistor DT may include a first active layer ACT1 and a gate electrode GE disposed on a portion of the first active layer ACT1. The first switching transistor ST1 may include a second active layer ACT2 and a gate electrode GE disposed on a portion of the second active layer ACT2. At least one gate insulating layer may be disposed between the active layer ACT and the gate electrode GE of each pixel transistor PXT.

In an embodiment, each of the pixel transistors PXT may include a source electrode electrically connected to a source region SR of the active layer ACT. Alternatively, the source region SR of the active layer ACT included in at least one pixel transistor PXT may be connected to another circuit element or line through at least one connection electrode or be formed integrally with a source region SR or a drain region DR included in an active layer ACT of another pixel transistor PXT.

Similarly, each of the pixel transistors PXT may include a drain electrode electrically connected to a drain region DR of the active layer ACT. Alternatively, the drain region DR of the active layer ACT included in at least one pixel transistor PXT may be connected to another circuit element or line through at least one connection electrode or be formed integrally with a source region SR or a drain region DR included in an active layer ACT of another pixel transistor PXT.

In an embodiment, a bottom electrode BE (or a light blocking pattern) may be disposed below the active layer ACT of each of the pixel transistors PXT. By disposing the bottom electrode BE below the active layer ACT, it is possible to block external light incident on a channel region CH or the like from a portion below the active layer ACT and stabilize operation characteristics of each of the pixel transistors PXT. However, embodiments are not limited thereto. As an example, the bottom electrodes BE may also be disposed only below some of the pixel transistors PXT.

In an embodiment, the bottom electrode BE may be utilized as a back-gate electrode (or a control electrode) electrically connected to each pixel transistor PXT to adjust characteristics of the pixel transistor PXT. In this case, the bottom electrode BE may be considered as a component included in the pixel transistor PXT.

The panel circuit layer PCL may further include a plurality of insulating layers disposed around the circuit elements and the lines. For example, the panel circuit layer PCL may include a barrier layer BRL, a buffer layer BFL, a first gate insulating layer GI1, a second gate insulating layer GI2, a first insulating layer INS1 (e.g., an interlayer insulating layer), and a second insulating layer INS2 (e.g., a planarization layer) that are sequentially disposed on the substrate SUB. The barrier layer BRL, the buffer layer BFL, the first gate insulating layer GI1, the second gate insulating layer GI2, the first insulating layer INS1, and the second insulating layer INS2 are disposed in the display area DA, and may also be disposed in at least a portion of the non-display area NDA. For example, the barrier layer BRL, the buffer layer BFL, the first gate insulating layer GI1, the second gate insulating layer GI2, the first insulating layer INS1, and the second insulating layer INS2 may also be disposed in the driving circuit area of the non-display area NDA.

The barrier layer BRL may include a material suitable for protecting the pixels PX from moisture permeating through the substrate SUB vulnerable to moisture permeation. As an example, the barrier layer BRL may include at least one inorganic layer including an inorganic insulating material (e.g., silicon nitride, silicon oxide, silicon oxynitride, titanium oxide, aluminum oxide, or other inorganic insulating materials).

The bottom electrodes BE may be disposed on the barrier layer BRL. The bottom electrodes BE may be disposed below the active layers ACT of the pixel transistors PXT.

Each of the bottom electrodes BE may include at least one conductive material. For example, each of the bottom electrodes BE may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), and other metals, alloys thereof, or other conductive materials. Each of the bottom electrodes BE may be formed as a single-layer or multilayer electrode.

The buffer layer BFL may be disposed on the bottom electrodes BE. For example, the buffer layer BFL may be disposed on the barrier layer BRL to cover the bottom electrodes BE.

The buffer layer BFL is a single layer or multiple layers including at least one insulating material, and may be formed as an insulating layer. For example, the buffer layer BFL may include at least one inorganic layer including an inorganic insulating material (e.g., silicon nitride, silicon oxide, silicon oxynitride, titanium oxide, aluminum oxide, or other inorganic insulating materials).

The active layers ACT may be disposed on the buffer layer BFL. The active layers ACT may include a first active layer ACT1 and a second active layer ACT2 having different structures.

Each active layer ACT may include a channel region CH overlapping each gate electrode GE, and a source region SR and a drain region DR respectively disposed on different sides of the channel region CH. The source region SR and the drain region DR may have a higher carrier concentration (e.g., electron concentration) than the channel region CH.

The first active layer ACT1 may be formed in a stacked structure including a plurality of oxide semiconductor layers having different mobility and/or crystal structures. For example, the first active layer ACT1 may include a first oxide semiconductor layer OS1 including a first oxide semiconductor and a second oxide semiconductor layer OS2 disposed on the first oxide semiconductor layer OS1 and including a second oxide semiconductor. In an embodiment, the first oxide semiconductor layer OS1 and the second oxide semiconductor layer OS2 may be bonded to each other in a vertical direction (e.g., the third direction D3). For example, a lower surface of the second oxide semiconductor layer OS2 may be in contact with an upper surface of the first oxide semiconductor layer OS1. In an embodiment, each of the first oxide semiconductor layer OS1 and the second oxide semiconductor layer OS2 may include a channel region CH overlapping the gate electrode GE of the driving transistor DT, and a source region SR and a drain region DR respectively disposed on different sides of the channel region CH.

Each of the first oxide semiconductor layer OS1 and the second oxide semiconductor layer OS2 may include an oxide semiconductor suitable for forming the active layer ACT of the pixel transistor PXT. For example, each of the first oxide semiconductor layer OS1 and the second oxide semiconductor layer OS2 may include metal oxide including at least one of indium (In), gallium (Ga), zinc (Zn), tin (Sn), hafnium (Hf), zirconium (Zr), and aluminum (Al). As an example, each of the first oxide semiconductor layer OS1 and the second oxide semiconductor layer OS2 may include at least one of zinc oxide (ZnO), zinc tin oxide (ZTO), indium zinc oxide (IZO), indium oxide (InO or In₂O₃), titanium oxide (TiO or TiO₂), indium gallium oxide (IGO), indium gallium zinc oxide (IGZO), indium gallium tin oxide (IGTO), indium zinc tin oxide (IZTO), and indium tin gallium zinc oxide (ITGZO), or other oxide semiconductors.

In an embodiment, the first oxide semiconductor layer OS1 may include a material having excellent etching resistance (e.g., high etching resistance) so that it may not be damaged or etched in a process of forming the second oxide semiconductor layer OS2. For example, the first oxide semiconductor forming the first oxide semiconductor layer OS1 may include a crystalline oxide semiconductor (c-OS) having excellent etching resistance. As an example, the first oxide semiconductor may include crystalline indium gallium oxide (p-IGO) having excellent etching resistance and high mobility (e.g., carrier mobility or electron mobility), but is not limited thereto.

In an embodiment, the second oxide semiconductor layer OS2 may have mobility different from that of the first oxide semiconductor layer OS1. For example, mobility of the second oxide semiconductor forming the second oxide semiconductor layer OS2 may be lower than the mobility of the first oxide semiconductor forming the first oxide semiconductor layer OS1. Accordingly, the first active layer ACT1 may have a heterojunction structure including the first oxide semiconductor layer OS1 having high mobility and the second oxide semiconductor layer OS2 having low mobility.

In describing embodiments, the high mobility and the low mobility only may express a relative mobility difference between the first oxide semiconductor and the second oxide semiconductor, and the mobility of each of the first oxide semiconductor and the second oxide semiconductor is not limited to a specific value or range. In addition, the mobility of the first oxide semiconductor and the mobility of the second oxide semiconductor may be values measured based on carrier mobility (e.g., electron mobility) of a portion (e.g., the channel region CH) where each of the first oxide semiconductor layer OS1 and the second oxide semiconductor layer OS2 maintains semiconductor characteristics.

In an embodiment, the second oxide semiconductor may include an amorphous oxide semiconductor (e.g., amorphous indium gallium zinc oxide (IGZO)) having mobility lower than the mobility of the crystalline first oxide semiconductor (e.g., crystalline indium gallium oxide (p-IGO)) included in the first oxide semiconductor layer OS1, but is not limited thereto. For example, the second oxide semiconductor may also include another amorphous or crystalline oxide semiconductor having mobility lower than the mobility of the first oxide semiconductor.

Since the first active layer ACT1 is formed in a stacked structure of the first oxide semiconductor layer OS1 having the high mobility and the second oxide semiconductor layer OS2 having the low mobility, performance (e.g., operation characteristics) and reliability of the driving transistor DT may be improved. For example, since the first active layer ACT1 includes the first oxide semiconductor layer OS1 having the higher mobility and the second oxide semiconductor layer OS2 having the lower mobility, a subthreshold swing of the driving transistor DT may be more stably secured (e.g., a subthreshold slope (SS) may be maintained in an appropriate range) and a data swing range (DSR) may be reduced. Accordingly, image quality of the display device 100 may be improved by more precisely controlling the driving current Id of the pixel PX even in a low gradation region where luminance of the pixel PX is controlled by the driving current Id that is fine. In addition, as the data swing range is reduced, power consumption of the display device 100 may be reduced.

In embodiments, the operation characteristics of the driving transistor DT may be adjusted by adjusting a ratio between and/or thicknesses of the first oxide semiconductor layer OS1 and the second oxide semiconductor layer OS2 of the first active layer ACT1. In an embodiment, a thickness of the first oxide semiconductor layer OS1 may fall in the range of ⅓0 to ½ of a thickness of the first active layer ACT1 (e.g., the sum of the thickness of the first oxide semiconductor layer OS1 and a thickness of the second oxide semiconductor layer OS2). For example, the total thickness of the first active layer ACT1 may be 300 Å, and the thickness of the first oxide semiconductor layer OS1 may fall in the range of 100 Å to 150 Å. In this case, the thickness of the second oxide semiconductor layer OS2 may fall in the range of 150 Å to 200 Å. As an example, when the thickness of the first oxide semiconductor layer OS1 is 100 Å, the thickness of the second oxide semiconductor layer OS2 may be 200 Å, and when the thickness of the first oxide semiconductor layer OS1 is 150 Å, the thickness of the second oxide semiconductor layer OS2 may also be 150 Å.

As described above, in embodiments, by optimizing the ratio between and/or the thicknesses of the first oxide semiconductor layer OS1 and the second oxide semiconductor layer OS2 constituting the first active layer ACT1, it is possible to stably secure the subthreshold swing (or the subthreshold slope) of the driving transistor DT and reduce the data swing range. On the other hand, when the thickness of the first oxide semiconductor layer OS1 is smaller than ⅓ of the total thickness of the first active layer ACT1 or smaller than 100 Å unlike embodiments, the mobility of the driving transistor DT may decrease and the data swing range may increase, such that power consumption of the display device 100 may increase. In addition, when the thickness of the first oxide semiconductor layer OS1 is greater than ½ of the total thickness of the first active layer ACT1 or greater than 150 Å unlike in embodiments, it may be difficult to stably secure the subthreshold swing of the driving transistor DT, and it may be likely that a malfunction such as early turn-on, a leakage current, or the like, of the driving transistor DT will occur.

The second active layer ACT2 may be formed in a single-layer structure including one type of oxide semiconductor layer. For example, the second active layer ACT2 may be formed as a second oxide semiconductor layer OS2 including a second oxide semiconductor. In an embodiment, the second oxide semiconductor layer OS2 of the first active layer ACT1 and the second active layer ACT2 may be formed simultaneously using the same second oxide semiconductor, and may have substantially the same thickness or similar thicknesses.

As the second active layer ACT2 is formed as the second oxide semiconductor layer OS2, a threshold voltage and reliability of the first switching transistor ST1 may be secured. For example, as the second active layer ACT2 included in the first switching transistor ST1 is formed as the second oxide semiconductor layer OS2 having low mobility, a malfunction (e.g., early turn-on) and a leakage current of the first switching transistor ST1 may be prevented. Accordingly, operation characteristics and reliability of the first switching transistor ST1 may be secured or improved.

The first gate insulating layer GI1 may be disposed on the active layers ACT. In an embodiment, the first gate insulating layer GI1 may be entirely disposed on the buffer layer BFL and the active layers ACT, but is not limited thereto. For example, the first gate insulating layer GI1 may also have a shape in which it is etched to cover only a portion of each of the active layers ACT including the channel regions CH and not cover the other portions (e.g., the source region SR and the drain region DR) of each of the active layers ACT.

The gate electrode GE of the first switching transistor ST1 may be disposed on the first gate insulating layer GI1. The gate electrode GE of the first switching transistor ST1 may face the channel region CH of the second active layer ACT2 with the first gate insulating layer GI1. The first gate insulating layer GI1 may be disposed between the gate electrode GE of the first switching transistor ST1 and the channel region CH of the second active layer ACT2.

In addition, the second gate insulating layer GI2 may be disposed on the first gate insulating layer GI1. In an embodiment, the second gate insulating layer GI2 may be entirely disposed on the gate electrode GE of the first switching transistor ST1 and the first gate insulating layer GI1 so as to cover the gate electrode GE of the first switching transistor ST1, but is not limited thereto. For example, the second gate insulating layer GI2 may be disposed only in a portion of the pixel area PXA corresponding to an area where the driving transistor DT is disposed, and may cover at least a portion of the first active layer ACT1 including the channel region CH. At least a portion of the first active layer ACT1 including the channel region CH may be covered with the first gate insulating layer GI1 and the second gate insulating layer GI2.

Each of the first gate insulating layer GI1 and the second gate insulating layer GI2 may be formed as a single-layer or multilayer insulating layer including at least one insulating material. For example, each of the first gate insulating layer GI1 and the second gate insulating layer GI2 may include at least one inorganic insulating layer including an inorganic insulating material (e.g., silicon oxide, silicon nitride, silicon oxynitride, titanium oxide, aluminum oxide, or other inorganic insulating materials).

The gate electrode GE of the driving transistor DT may be disposed on the second gate insulating layer GI2. The gate electrode GE of the driving transistor DT may face the channel region CH of the first active layer ACT1 with the first gate insulating layer GI1 and the second gate insulating layer GI2. The first gate insulating layer GI1 and the second gate insulating layer GI2 may be disposed between the gate electrode GE of the driving transistor DT and the channel region CH of the first active layer ACT1.

As the gate electrode GE of the driving transistor DT is disposed on the second gate insulating layer GI2, a thickness of the gate insulating layer interposed between the gate electrode GE of the driving transistor DT and the first active layer ACT1 may be increased. For example, only the first gate insulating layer GI1 is interposed between the gate electrode GE of the first switching transistor ST1 and the second active layer ACT2, whereas the first gate insulating layer GI1 and the second gate insulating layer GI2 are interposed between the gate electrode GE of the driving transistor DT and the first active layer ACT1, such that a thickness of the gate insulating layer of the driving transistor DT may increase compared to a thickness of the gate insulating layer of the first switching transistor ST1. Accordingly, the subthreshold swing (or the subthreshold slope) of the driving transistor DT may be more stably secured.

The gate electrode GE of each of the pixel transistors PXT including the first switching transistor ST1 and the driving transistor DT may include at least one conductive material. For example, each of the gate electrodes GE may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), and other metals, alloys thereof, or other conductive materials. Each gate electrode GE may be formed as a single-layer or multilayer electrode.

The first insulating layer INS1 may be disposed on the second gate insulating layer GI2 and the pixel transistors PXT (or the gate electrodes GE of the pixel transistors PXT). The first insulating layer INS1 may entirely cover the pixel transistors PXT (or the active layers ACT and the gate electrodes GE of the pixel transistors PXT) and the first and second gate insulating layers GI1 and GI2.

The first insulating layer INS1 may be formed as a single-layer or multilayer insulating layer including at least one insulating material. For example, the first insulating layer INS1 may include at least one inorganic insulating layer including an inorganic insulating material (e.g., silicon oxide, silicon nitride, silicon oxynitride, titanium oxide, aluminum oxide, or other inorganic insulating materials).

A plurality of connection electrodes (or a source electrode and/or a drain electrode of at least one pixel transistor PXT) electrically connected to at least some pixel transistors PXT may be disposed on the first insulating layer INS1. As an example, a first connection electrode CE1 and a second connection electrode CE2 that are electrically connected to the driving transistor DT and a third connection electrode CE3 electrically connected to the first switching transistor ST1 may be disposed on the first insulating layer INS1.

The first connection electrode CE1 may be electrically connected to the source region SR of the first active layer ACT1. For example, the first connection electrode CE1 may be electrically connected to the source region SR of the first active layer ACT1 through at least one contact hole penetrating through the first gate insulating layer GI1, the second gate insulating layer GI2, and the first insulating layer INS1. The first connection electrode CE1 may also function as a source electrode of the driving transistor DT. In this case, the first connection electrode CE1 may be considered as a component included in the driving transistor DT. In an embodiment, when the driving transistor DT is the first transistor T1 of FIG. 3, the first connection electrode CE1 may be electrically connected to the third node N3 or may constitute the third node N3.

The second connection electrode CE2 may be electrically connected to the drain region DR of the first active layer ACT1. For example, the second connection electrode CE2 may be electrically connected to the drain region DR of the first active layer ACT1 through at least one contact hole penetrating through the first gate insulating layer GI1, the second gate insulating layer GI2, and the first insulating layer INS1. The second connection electrode CE2 may also function as a drain electrode of the driving transistor DT. In this case, the second connection electrode CE2 may be considered as a component included in the driving transistor DT. In an embodiment, when the driving transistor DT is the first transistor T1 of FIG. 3, the second connection electrode CE2 may be electrically connected to the second node N2 or may constitute the second node N2. In another embodiment, the panel circuit layer PCL may not include the second connection electrode CE2. In this case, the drain region DR of the first active layer ACT1 may be directly connected to another circuit element, line, or the like. As an example, when the driving transistor DT is the first transistor T1 of FIG. 3, the drain region DR of the first active layer ACT1 may be formed integrally with a source region of the fifth transistor T5 of FIG. 3 or be directly connected or bonded to the source region or a source electrode of the fifth transistor T5.

The third connection electrode CE3 may be electrically connected to the source region SR of the second active layer ACT2. For example, the third connection electrode CE3 may be electrically connected to the source region SR of the second active layer ACT2 through at least one contact hole penetrating through the first gate insulating layer GI1, the second gate insulating layer GI2, and the first insulating layer INS1. The third connection electrode CE3 may also function as a source electrode of the first switching transistor ST1. In this case, the third connection electrode CE3 may be considered as a component included in the first switching transistor ST1. In an embodiment, when the first switching transistor ST1 is the sixth transistor T6 of FIG. 3, the third connection electrode CE3 may be electrically connected to a first electrode ET1 of the light emitting element ED.

The panel circuit layer PCL may or may not additionally include a connection electrode electrically connected to the drain region DR of the second active layer ACT2. When the panel circuit layer PCL includes the connection electrode connected to the drain region DR of the second active layer ACT2, the drain region DR of the second active layer ACT2 may be electrically connected to another circuit element or line through the connection electrode. When the panel circuit layer PCL does not include the connection electrode connected to the drain region DR of the second active layer ACT2, the drain region DR of the second active layer ACT2 may be directly connected or bonded to another circuit element or line or be formed integrally with an active layer ACT of another pixel transistor PXT. In an embodiment, when the first switching transistor ST1 is the sixth transistor T6 of FIG. 3, the drain region DR of the second active layer ACT2 may be electrically connected to the first connection electrode CE1 in an area not illustrated or may be formed integrally with at least a portion of the first active layer ACT1 (e.g., the second oxide semiconductor layer OS2 of the first active layer ACT1).

Each of the plurality of connection electrodes including the first connection electrode CE1, the second connection electrode CE2, the third connection electrode CE3, and the like, may include at least one conductive material. For example, each of the plurality of connection electrodes may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), and other metals, alloys thereof, or other conductive materials. Each of the plurality of connection electrodes may be formed as a single-layer or multilayer electrode.

The second insulating layer INS2 may be disposed on the first insulating layer INS1 and the plurality of connection electrodes. The second insulating layer INS2 may be formed as a single-layer or multilayer insulating layer including at least one insulating material. For example, the second insulating layer INS2 may include at least one organic insulating layer including an organic insulating material (e.g., an acrylic resin, an epoxy resin, a phenolic resin, a polyamide resin, a polyimide resin, or other organic insulating materials). The second insulating layer INS2 may include an inorganic insulating layer or may not include an inorganic insulating layer. A surface (e.g., an upper surface) of the second insulating layer INS2 may be substantially flat. The second insulating layer INS2 may alleviate or planarize a step due to the circuit elements (e.g., the pixel transistors PXT) and the lines of the panel circuit layer PCL.

The light emitting element layer LEL may be disposed on the panel circuit layer PCL. For example, the light emitting element layer LEL may be disposed on the second insulating layer INS2, and may be located at least in the display area DA.

The light emitting element layer LEL may include a light emitting element LD of each of the pixels PX. For example, the light emitting element layer LEL may include a pixel defining layer PDL (also referred to as a “bank”) partitioning an emission area of each of the pixels PX and the light emitting element ED located in each emission area. In an embodiment, the light emitting element layer LEL may further include a spacer SPC disposed on a portion of the pixel defining layer PDL.

Each light emitting element ED may include a first electrode ET1 located in each emission area and a light emitting layer EML and a second electrode ET2 that are sequentially located on the first electrode ET1. The first electrode ET1 of the light emitting element ED may be electrically connected to at least one pixel transistor PXT included in the corresponding pixel PX. For example, the first electrode ET1 of the light emitting element ED may be electrically connected to the third connection electrode CE3 through a via hole (or a contact hole) penetrating through the second insulating layer INS2, and may be electrically connected to at least one pixel transistor PXT (e.g., the sixth transistor T6) through the third connection electrode CE3.

The first electrode ET1 of the light emitting element ED may be a single-layer or multilayer electrode including at least one conductive material. In an embodiment, the display panel 110 may be a top emission-type display panel, and the first electrode ET1 may include a reflective electrode layer having high reflectivity.

The light emitting layer EML of the light emitting element ED may include a high molecular material or a low molecular material, and may emit light of a specific color (or a specific wavelength band). As an example, the light emitting layer EML may emit red light, green light, blue light, white light, or light of other colors. The light emitting layer EML may include a single light generating layer or may be formed in a tandem structure including a plurality of light generating layers and at least one intermediate layer (e.g., a charge generating layer, etc.). Light emitted from the light emitting layer EML may contribute to image display.

In an embodiment, the light emitting layer EML may be individually formed in the emission area of each pixel PX, and may emit light corresponding to an emission wavelength of each pixel PX. As an example, the light emitting layer EML included in a red pixel may emit light of a red wavelength band, the light emitting layer EML included in a green pixel may emit light of a green wavelength band, and the light emitting layer EML included in a blue pixel may emit light of a blue wavelength band.

In another embodiment, the light emitting layer EML may be a common layer formed over the entire display area DA, and may emit light of a specific wavelength band (e.g., blue light or white light). In this case, a light conversion layer for converting light emitted from the light emitting element ED into light corresponding to an emission wavelength of at least one pixel PX may be disposed on the light emitting element ED of at least one pixel PX.

The second electrode ET2 of the light emitting element ED may include a conductive material. In an embodiment, the second electrode ET2 may be a common layer formed over the entire display area DA so as to covers the light emitting layer EML and the pixel defining layer PDL. In an embodiment, the display panel 110 may be a top emission-type display panel, and the second electrode ET2 may include a transparent or translucent electrode layer.

The pixel defining layer PDL may have an opening corresponding to each emission area, and may surround each emission area. For example, the pixel defining layer PDL may cover an edge portion of the first electrode ET1 of the light emitting element ED, and may include an opening exposing the other portion of the first electrode ET1. An area where the exposed first electrode ET1 and the light emitting layer EML overlap each other may be the emission area of each pixel PX. In an embodiment, the pixel defining layer PDL may include at least one organic insulating layer including an organic insulating material.

The pixel defining layer PDL may be disposed at least in the display area DA. In an embodiment, the pixel defining layer PDL may also be disposed in at least a portion of the non-display area NDA. As an example, the pixel defining layer PDL may also be disposed in the driving circuit area of the non-display area NDA to cover the driver transistors disposed in the driving circuit area.

The spacer SPC may be disposed on a portion of the pixel defining layer PDL. The spacer SPC may include at least one organic layer including an organic insulating material. The spacer SPC may include the same material as the pixel defining layer PDL or include a different material from the pixel defining layer PDL. The pixel defining layer PDL and the spacer SPC may be sequentially formed through respective mask processes or may be formed simultaneously and/or integrally with each other using a halftone mask.

The encapsulation layer ENL may be disposed on the light emitting element layer LEL. The encapsulation layer ENL may cover the light emitting element layer LEL in the display area DA and extend to the non-display area NDA to be in contact with the panel circuit layer PCL. The encapsulation layer ENL may block permeation of oxygen or moisture into the light emitting element layer LEL and alleviate an electrical or physical shock to the panel circuit layer PCL and the light emitting element layer LEL.

In an embodiment, the encapsulation layer ENL may include a first encapsulation layer ENL1, a second encapsulation layer ENL2, and a third encapsulation layer ENL3 that are sequentially disposed on the light emitting element layer LEL. Each of the first encapsulation layer ENL1 and the third encapsulation layer ENL3 may be an inorganic encapsulation layer including an inorganic material. The second encapsulation layer ENL2 may be an organic encapsulation layer including an organic material.

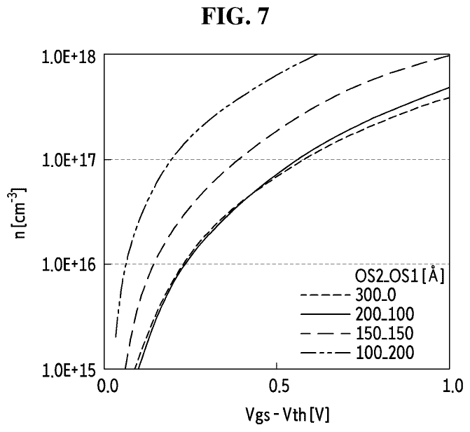

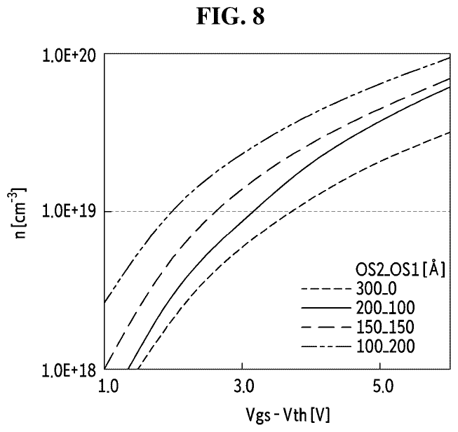

FIGS. 7 and 8 are graphs illustrating a change in characteristics of a driving transistor according to thicknesses of a first oxide semiconductor layer and a second oxide semiconductor layer. For example, FIG. 7 illustrates an electron concentration n in the first active layer ACT1 according to the thicknesses of the first oxide semiconductor layer OS1 and the second oxide semiconductor layer OS2 of the first active layer ACT1 in a low gradation region where a gate overdrive voltage (difference voltage (Vgs-Vth) between a gate-source voltage Vgs and a threshold voltage Vth) of the driving transistor DT is 1.0 V or less. In addition, FIG. 8 illustrates an electron concentration n in the first active layer ACT1 according to the thicknesses of the first oxide semiconductor layer OS1 and the second oxide semiconductor layer OS2 of the first active layer ACT1 in a high grayscale region where the gate overdrive voltage (Vgs-Vth) of the driving transistor DT is 1.0 V or more.

Referring to FIGS. 7 and 8 in addition to FIG. 6, when the first active layer ACT1 having the thickness of 300 Å is formed only as the second oxide semiconductor layer OS2 having a thickness of 300 Å, the electron concentration n in the first active layer ACT1 may be low in both the low grayscale region and the high grayscale region. In this case, the subthreshold swing (or the subthreshold slope) of the driving transistor DT may be stably secured, but the data swing range for obtaining target luminance may increase, such that power consumption of the display device 100 may increase.

On the other hand, when the first active layer ACT1 having the thickness of 300 Å includes the first oxide semiconductor layer OS1 having a thickness of 200 Å and the second oxide semiconductor layer OS2 having a thickness of 100 Å, the electron concentration n in the first active layer ACT1 may be high in both the low gradation region and the high gradation region. In this case, the data swing range may be reduced, but it is difficult to stably secure the subthreshold swing (or the subthreshold slope) of the driving transistor DT, such that image quality of the display device 100 may be deteriorated.

When the first oxide semiconductor layer OS1 included in the first active layer ACT1 having the thickness of 300 Å is formed at a thickness of 100 Å to 150 Å as in embodiments, operation characteristics of the driving transistor DT may be optimized. For example, when the first oxide semiconductor layer OS1 and the second oxide semiconductor layer OS2 included in the first active layer ACT1 having the thickness of 300 Å are formed at a thickness of 100 Å and a thickness of 200 Å, respectively, or each of the first oxide semiconductor layer OS1 and the second oxide semiconductor layer OS2 is formed at a thickness of 150 Å, the subthreshold swing of the driving transistor DT may be stably secured and the data swing range may be reduced. Accordingly, the power consumption of the display device 100 may be reduced and the image quality of the display device 100 may be secured and improved.

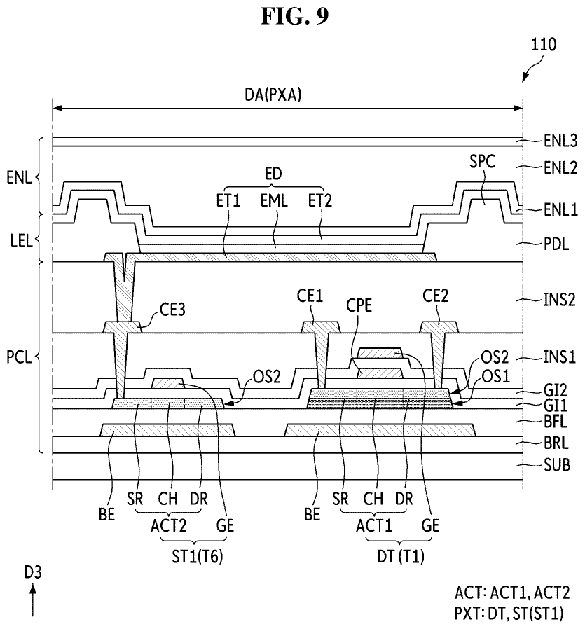

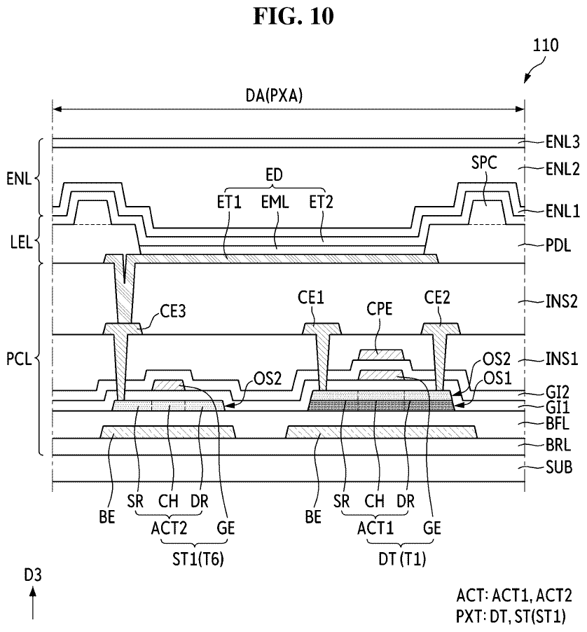

FIG. 9 is a cross-sectional view illustrating a portion of a display panel according to an embodiment. FIG. 10 is a cross-sectional view illustrating a portion of a display panel according to an embodiment. For example, FIGS. 9 and 10 illustrate a portion of a pixel area PXA included in the display area DA of the display panel 110.

Compared to FIG. 6, FIGS. 9 and 10 further illustrate a capacitor electrode CPE disposed around the driving transistor DT, and illustrate different embodiments with respect to locations of the gate electrode GE of the driving transistor DT and the capacitor electrode CPE. Each embodiment disclosed herein may be implemented alone or in combination with at least one other embodiment. In describing the following embodiments, an overlapping description of the components described above will be omitted.

Referring to FIGS. 9 and 10 in addition to FIG. 6, the display panel 110 may further include a capacitor electrode CPE overlapping the gate electrode GE of the driving transistor DT. The gate electrode GE of the driving transistor DT and the capacitor electrode CPE may face each other with the second gate insulating layer GI2. The second gate insulating layer GI2 may be disposed between the gate electrode GE of the driving transistor DT and the capacitor electrode CPE. A capacitor (e.g., the first capacitor C1 of FIG. 3) may be formed by capacitance formed between the gate electrode GE of the driving transistor DT and the capacitor electrode CPE.

In an embodiment, as illustrated in FIG. 9, the gate electrode GE of the driving transistor DT may be disposed on the second gate insulating layer GI2, and the capacitor electrode CPE may be disposed on the first gate insulating layer GI1. For example, the capacitor electrode CPE may be disposed between the first gate insulating layer GI1 and the second gate insulating layer GI2, and may overlap the gate electrode GE of the driving transistor DT.

In another embodiment, as illustrated in FIG. 10, the gate electrode GE of the driving transistor DT may be disposed on the first gate insulating layer GI1. For example, the gate electrode GE of the driving transistor DT may be disposed between the first gate insulating layer GI1 and the second gate insulating layer GI2. In this case, the capacitor electrode CPE may be disposed on the second gate insulating layer GI2.

As in embodiments of FIGS. 9 and 10, the gate electrode GE of the driving transistor DT may be disposed on the first gate insulating layer GI1 or the second gate insulating layer GI2, and operation characteristics of the driving transistor DT may be changed depending on a thickness of a gate insulating layer (e.g., the first gate insulating layer GI1 and/or the second gate insulating layer GI2) interposed between the gate electrode GE of the driving transistor DT and the first active layer ACT1. For example, the operation characteristics of the driving transistor DT may be adjusted by adjusting or changing a location of the gate electrode GE of the driving transistor DT.

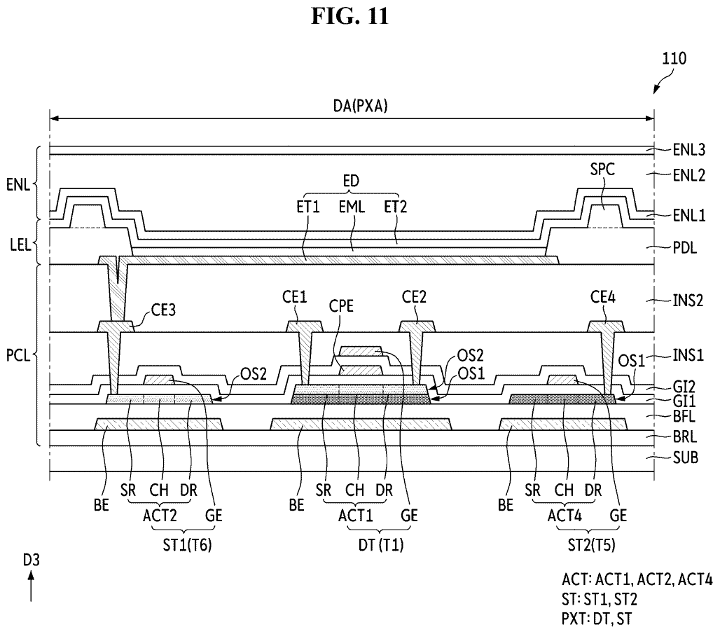

FIG. 11 is a cross-sectional view illustrating a portion of a display panel according to an embodiment. For example, FIG. 11 illustrates a portion of a pixel area PXA included in the display area DA of the display panel 110.

Compared to FIGS. 6, 9, and 10, FIG. 11 further illustrates a second switching transistor ST2. For example, FIG. 11 further illustrates a second switching transistor ST2 together with the driving transistor DT and the first switching transistor ST1 of FIG. 9 as an example of circuit elements that may be included in the pixel PX.

Referring to FIG. 11 in addition to FIGS. 6, 9, and 10, the display panel 110 may further include a second switching transistor ST2 disposed in each pixel area PXA. The “second switching transistor ST2” may refer to a switching transistor ST including a first oxide semiconductor layer OS1 among the switching transistors ST of the pixel PX.

The second switching transistor ST2 may include a fourth active layer ACT4 disposed on the buffer layer BFL and a gate electrode GE disposed on a portion (e.g., a channel region CH) of the fourth active layer ACT4. The “fourth active layer ACT4” may refer to an active layer ACT of the second switching transistor ST2. In an embodiment, the gate electrode GE of the second switching transistor ST2 may be disposed on the first gate insulating layer GI1. The gate electrode GE of the second switching transistor ST2 may face the channel region CH of the fourth active layer ACT4 with the first gate insulating layer GI1. The first gate insulating layer GI1 may be disposed between the gate electrode GE of the second switching transistor ST2 and the channel region CH of the fourth active layer ACT4.

The active layers ACT of the first switching transistor ST1 and the second switching transistor ST2 may include different oxide semiconductors. For example, the first switching transistor ST1 may include a second active layer ACT2 including a second oxide semiconductor, and the second switching transistor ST2 may include the fourth active layer ACT4 including a first oxide semiconductor. Since the second switching transistor ST2 includes the first oxide semiconductor having high mobility, the second switching transistor ST2 may have higher mobility than the first switching transistor ST1.

The active layers ACT of the driving transistor DT and the second switching transistor ST2 may have different structures. For example, the driving transistor DT may include a first active layer ACT1 of a double-layer structure including a first oxide semiconductor layer OS1 and a second oxide semiconductor layer OS2, and the second switching transistor ST2 may include the fourth active layer ACT4 of a single-layer structure including the first oxide semiconductor layer OS1. In an embodiment, the first oxide semiconductor layer OS1 of the first active layer ACT1 and the fourth active layer ACT4 may be formed simultaneously using the same first oxide semiconductor, and may have substantially the same thickness or similar thicknesses.

In an embodiment, at least one switching transistor ST relatively insensitive to a threshold voltage and requiring a high current driving capability among the switching transistors ST of the pixel PX may be formed as the second switching transistor ST2. As an example, the fifth transistor T5 electrically connected between the first power line VDL and the driving transistor DT among the switching transistors ST of FIG. 3 may be formed as the second switching transistor ST2 having high mobility. Accordingly, a gate-on voltage (e.g., a high-level voltage of the first emission control signal EM1) of the fifth transistor T5 may be lowered, and power consumption of the display device 100 may be improved. In addition, each of the other switching transistors ST of FIG. 3 such as the second transistor T2, the third transistor T3, the fourth transistor T4, and the sixth transistor T6 is formed as the first switching transistor ST1 having low mobility, which is advantageous in stably securing a threshold voltage, such that a malfunction of the pixel PX may be prevented and reliability of the display device 100 may be improved. However, embodiments are not limited thereto. For example, in another embodiment, all of the switching transistors ST of the pixel PX may also be formed as the first switching transistors ST1 having the low mobility.

In an embodiment, the panel circuit layer PCL may include at least one connection electrode electrically connected to the second switching transistor ST2. For example, the panel circuit layer PCL may include a fourth connection electrode CE4 electrically connected to a drain region DR of the fourth active layer ACT4.

The fourth connection electrode CE4 may be disposed on the first insulating layer INS1. The fourth connection electrode CE4 may include a conductive material included in the first connection electrode CE1, the second connection electrode CE2, and/or the third connection electrode CE3.

The fourth connection electrode CE4 may be electrically connected to the drain region DR of the fourth active layer ACT4 through at least one contact hole penetrating through the first gate insulating layer GI1, the second gate insulating layer GI2, and the first insulating layer INS1. The fourth connection electrode CE4 may also function as a drain electrode of the second switching transistor ST2. In this case, the fourth connection electrode CE4 may be considered as a component included in the second switching transistor ST2. In an embodiment, when the second switching transistor ST2 is the fifth transistor T5 of FIG. 3, the fourth connection electrode CE4 may be electrically connected to the first power line VDL or may be a portion of the first power line VDL.

The panel circuit layer PCL may or may not additionally include a connection electrode electrically connected to a source region SR of the fourth active layer ACT4. When the panel circuit layer PCL includes the connection electrode connected to the source region SR of the fourth active layer ACT4, the source region SR of the fourth active layer ACT4 may be electrically connected to another circuit element or line through the connection electrode. When the panel circuit layer PCL does not include the connection electrode connected to the source region SR of the fourth active layer ACT4, the source region SR of the fourth active layer ACT4 may be directly connected or bonded to another circuit element or line or be formed integrally with an active layer ACT of another pixel transistor PXT. In an embodiment, when the second switching transistor ST2 is the fifth transistor T5 of FIG. 3, the source region SR of the fourth active layer ACT4 may be electrically connected to the second connection electrode CE2 in an area not illustrated or be formed integrally with at least a portion of the first active layer ACT1 (e.g., the first oxide semiconductor layer OS1 of the first active layer ACT1).

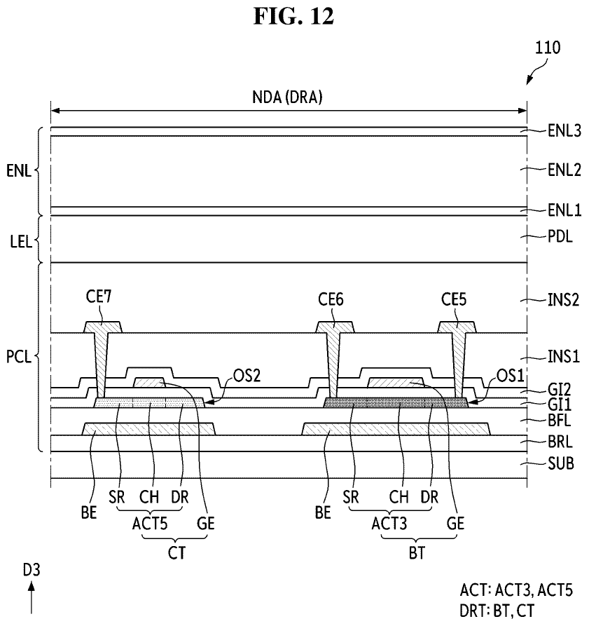

FIG. 12 is a cross-sectional view illustrating a portion of a display panel according to an embodiment. For example, FIG. 12 illustrates a portion of a driving circuit area DRA included in the non-display area NDA of the display panel 110.

Referring to FIG. 12 in addition to FIGS. 1 to 11, circuit elements included in the stages STG of the first driving circuit 120 may be disposed in the driving circuit area DRA of the non-display area NDA. The circuit elements of the first driving circuit 120 may include driver transistors DRT.

In an embodiment, the driver transistors DRT may include a plurality of control transistors CT including a control transistor CT of FIG. 12 and a plurality of buffer transistors BT including a buffer transistor BT of FIG. 12. FIG. 12 illustrates one control transistor CT and one buffer transistor BT that may be included in any stage STG as an example of the driver transistors DRT. For example, the control transistor CT of FIG. 12 may be one of the control transistors included in the control circuit NC of FIG. 5, and the buffer transistor BT of FIG. 12 may be one of the first and second pull-up transistors PUT1 and PUT2 and the first and second pull-down transistors PDT1 and PDT2 included in the first output circuit OB1 and the second output circuit OB2 of FIG. 5.

The buffer transistor BT may include a third active layer ACT3 disposed on the buffer layer BFL and a gate electrode GE disposed on a portion (e.g., a channel region CH) of the third active layer ACT3. The “third active layer ACT3” may refer to an active layer ACT of the buffer transistor BT. In an embodiment, the gate electrode GE of the buffer transistor BT may be disposed on the first gate insulating layer GI1. The gate electrode GE of the buffer transistor BT may face the channel region CH of the third active layer ACT3 with the first gate insulating layer GI1. The first gate insulating layer GI1 may be disposed between the gate electrode GE of the buffer transistor BT and the channel region CH of the third active layer ACT3. In an embodiment, a bottom electrode BE may be disposed below the third active layer ACT3.

In an embodiment, the buffer transistor BT may include a first oxide semiconductor having high mobility, and accordingly, may be a high-mobility transistor having a high current driving capability. For example, the third active layer ACT3 of the buffer transistor BT may be formed as a single layer including a first oxide semiconductor layer OS1 including the first oxide semiconductor. In an embodiment, the first oxide semiconductor layer OS1 of the first active layer ACT1, the third active layer ACT3, and the fourth active layer ACT4 may be formed simultaneously using the same first oxide semiconductor, and may have substantially the same thickness or similar thicknesses.

Since the third active layer ACT3 has excellent mobility, a current may smoothly flow through the third active layer ACT3 even though a width of the third active layer ACT3 is not great. Accordingly, a size (e.g., an area) of the buffer transistor BT may be reduced to reduce an area occupied by the first driving circuit 120 and reduce and minimize the non-display area NDA of the display device 100.

In an embodiment, some or all of the buffer transistors BT included in each stage STG may be formed as high-mobility buffer transistors BT each including the third active layer ACT3 according to an embodiment of FIG. 12. For example, each of the first pull-up transistor PUT1 and the first pull-down transistor PDT1 included in the first output circuit OB1 of each stage STG may be formed as the high-mobility buffer transistor BT including the third active layer ACT3. Accordingly, a size of the first output circuit OB1 may be reduced. In an embodiment, each of the first and second pull-up transistors PUT1 and PUT2 and the first and second pull-down transistors PDT1 and PDT2 included in the first output circuit OB1 and the second output circuit OB2 of each stage STG may be formed as the high-mobility buffer transistor BT including the third active layer ACT3 according to an embodiment of FIG. 12. Accordingly, sizes of the first output circuit OB1 and the second output circuit OB2 may be reduced, and an area occupied by the first driving circuit 120 may be reduced more effectively.

The control transistor CT may include a fifth active layer ACT5 disposed on the buffer layer BFL and a gate electrode GE disposed on a portion (e.g., a channel region CH) of the fifth active layer ACT5. The “fifth active layer ACT5” may refer to an active layer ACT of the control transistor CT. In an embodiment, the gate electrode GE of the control transistor CT may be disposed on the first gate insulating layer GI1. The gate electrode GE of the control transistor CT may face the channel region CH of the fifth active layer ACT5 with the first gate insulating layer GI1. The first gate insulating layer GI1 may be disposed between the gate electrode GE of the control transistor CT and the channel region CH of the fifth active layer ACT5. In an embodiment, a bottom electrode BE may be disposed below the fifth active layer ACT5.

In an embodiment, the control transistor CT may be a transistor that includes a second oxide semiconductor having relatively low mobility and has high reliability. For example, the fifth active layer ACT5 of the control transistor CT may be formed as a single layer including a second oxide semiconductor layer OS2 including the second oxide semiconductor. In an embodiment, the second oxide semiconductor layer OS2 of the first active layer ACT1, the second active layer ACT2, and the fifth active layer ACT5 may be formed simultaneously using the same second oxide semiconductor, and may have substantially the same thickness or similar thicknesses.

As the fifth active layer ACT5 is formed as the second oxide semiconductor layer OS2, a threshold voltage and reliability of the control transistor CT may be secured. Accordingly, operation characteristics and reliability of the control transistor CT and the first driving circuit 120 including the control transistor CT may be secured or improved.

In an embodiment, a plurality of connection electrodes electrically connected to at least some driver transistors DRT may be disposed in the driving circuit area DRA. As an example, a fifth connection electrode CE5 and a sixth connection electrode CE6 electrically connected respectively to a drain region DR and a source region SR of the buffer transistor BT, a seventh connection electrode CE7 electrically connected to a source region SR (or a drain region DR) of the control transistor CT, and the like, may be disposed on the first insulating layer INS1. By appropriately connecting the driver transistors DRT to each other using the connection electrodes of the driving circuit area DRA, it is possible to form the stage STG of the first driving circuit 120.

The connection electrodes of the driving circuit area DRA may be covered with the second insulating layer INS2. In an embodiment, the pixel defining layer PDL and the encapsulation layer ENL may be sequentially disposed on the second insulating layer IN2. As an example, the pixel defining layer PDL and the encapsulation layer ENL may also be disposed in a portion of the non-display area NDA including the driving circuit area DRA to cover the driver transistors DRT. However, embodiments are not limited thereto. For example, at least one of the pixel defining layer PDL and the encapsulation layer ENL may not overlap the driver transistors DRT.

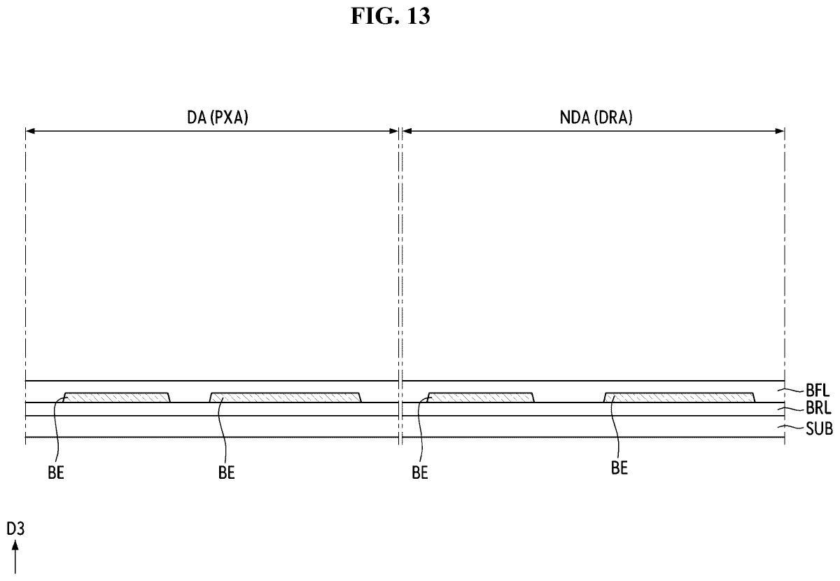

FIGS. 13 to 20 are cross-sectional views illustrating a method for manufacturing the display device according to an embodiment. For example, FIGS. 13 to 20 are cross-sectional views illustrating a method for manufacturing the display panel 110 included in the display device 100 according to an embodiment, and sequentially illustrate processes of manufacturing the panel circuit layer PCL including the pixel transistors PXT and the driver transistors DRT according to embodiments of FIGS. 6 to 12 and processes of manufacturing the light emitting element layer LEL on the panel circuit layer PCL.

Referring to FIG. 13 in addition to FIGS. 1 to 12, the substrate SUB including the display area DA and the non-display area NDA may be prepared, and the barrier layer BRL, the bottom electrodes BE, and the buffer layer BFL may be sequentially formed on the substrate SUB.

For example, the barrier layer BRL may be first formed on the substrate SUB. The barrier layer BRL may be formed by a process of forming an insulating film including the insulating material exemplified above. As an example, the barrier layer BRL may be formed by depositing an inorganic insulating material on the substrate SUB.

Subsequently, the bottom electrodes BE may be formed on the barrier layer BRL. The bottom electrodes BE may be formed by a process of forming a conductive film including a conductive material (e.g., at least one conductive material exemplified above) and a process of patterning the conductive film. In an embodiment, the process of patterning the conductive film may include a photolithography process. For example, the process of patterning the conductive film may include a photoresist process of forming a photoresist pattern required for etching the conductive film in a shape corresponding to the bottom electrodes BE and an etching process of forming the bottom electrodes BE from the conductive film by etching the conductive film using the photoresist pattern as a mask. However, a patterning method for forming the bottom electrodes BE is not limited thereto.

Subsequently, the buffer layer BFL may be formed on the substrate SUB, the barrier layer BRL, and the bottom electrodes BE. The buffer layer BFL may be formed by a process of forming an insulating film including at least one insulating material (e.g., an inorganic insulating material) exemplified above.

When the display panel 110 does not include at least one of the barrier layer BRL, the bottom electrodes BE, and the buffer layer BFL, a process of forming at least one of the barrier layer BRL, the bottom electrodes BE, and the buffer layer BFL may be omitted.

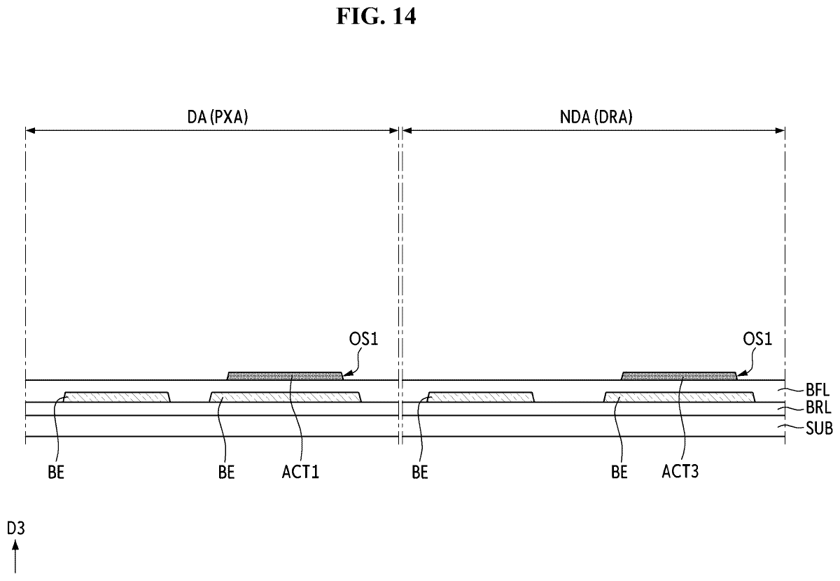

Referring to FIG. 14 in addition to FIGS. 1 to 13, the first oxide semiconductor layers OS1 may be formed on the buffer layer BFL. The first oxide semiconductor layer OS1 may be made of the first oxide semiconductor.

For example, the first oxide semiconductor layer OS1 for forming the first active layer ACT1 of the driving transistor DT may be formed in each pixel area PXA of the display area DA, and at the same time, the first oxide semiconductor layer OS1 for forming the third active layer ACT3 of the buffer transistor BT may be formed in the driving circuit area DRA of the non-display area NDA. When the pixel PX further includes the second switching transistor ST2 including the first oxide semiconductor layer OS1 as in an embodiment of FIG. 11, the first oxide semiconductor layer OS1 for forming the fourth active layer ACT4 of the second switching transistor ST2 may be further formed in each pixel area PXA.

The first oxide semiconductor layer OS1 may include the crystalline high-mobility oxide semiconductor (e.g., crystalline indium gallium oxide (p-IGO)) exemplified above as the first oxide semiconductor. For example, a first semiconductor pattern corresponding to each first oxide semiconductor layer OS1 may be formed by forming a first semiconductor layer including an amorphous oxide semiconductor (e.g., amorphous indium gallium oxide (IGO)) including indium (In) and gallium (Ga) on the buffer layer BFL and then etching the first semiconductor layer. Subsequently, the first oxide semiconductor layer OS1 including the crystalline first oxide semiconductor (e.g., crystalline indium gallium oxide (p-IGO)) may be formed by performing a crystallization process (e.g., an annealing process) of crystallizing the first semiconductor pattern to crystallize the amorphous oxide semiconductor included in the first semiconductor pattern.

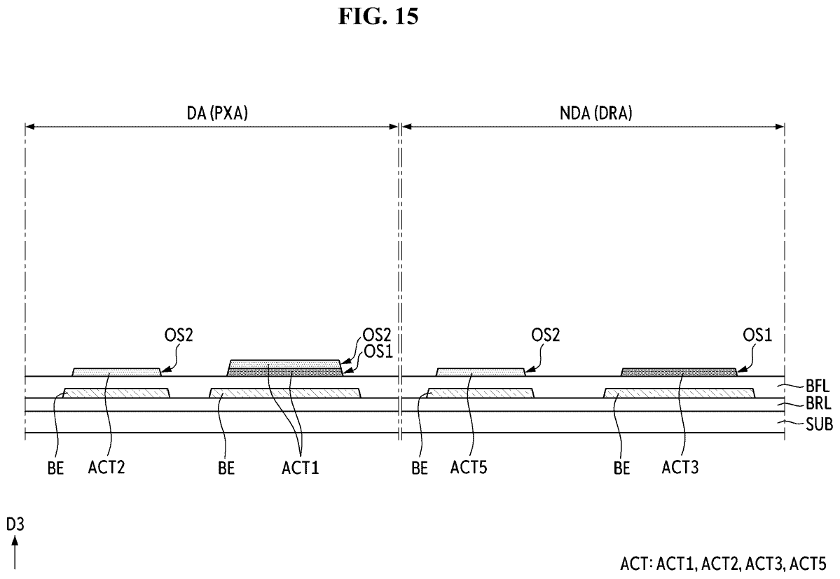

Referring to FIG. 15 in addition to FIGS. 1 to 14, the second oxide semiconductor layers OS2 may be formed on the first oxide semiconductor layer OS1 of the first active layer ACT1 and the buffer layer BFL. The second oxide semiconductor layer OS2 may be made of the second oxide semiconductor, and may have mobility lower than mobility of the first oxide semiconductor layer OS1.

For example, the second oxide semiconductor layer OS2 for forming the first active layer ACT1 of the driving transistor DT and the second oxide semiconductor layer OS2 for forming the second active layer ACT2 of the first switching transistor ST1 may be formed in each pixel area PXA of the display area DA, and at the same time, the second oxide semiconductor layer OS2 for forming the fifth active layer ACT5 of the control transistor CT may be formed in the driving circuit area DRA of the non-display area NDA.

The second oxide semiconductor layer OS2 may include the amorphous or crystalline low-mobility oxide semiconductor (e.g., amorphous indium gallium zinc oxide (IGZO)) exemplified above as the second oxide semiconductor. For example, the respective second oxide semiconductor layers OS2 may be formed by forming an amorphous second semiconductor layer (e.g., a second semiconductor layer including amorphous indium gallium zinc oxide (IGZO)) including indium (In) and zinc (Zn) on the buffer layer BFL and the first oxide semiconductor layer OS1 and then etching the second semiconductor layer.

Etching resistance of the first oxide semiconductor layer OS1 may be enhanced by the crystallization process performed before the second oxide semiconductor layer OS2 is formed. Accordingly, damage to or removal of the first oxide semiconductor layer OS1 by an etching process for forming the second oxide semiconductor layer OS2 may be prevented.

The active layers ACT of the pixel transistors PXT and the driver transistors DRT may be formed by the processes described with reference to FIGS. 14 and 15. For example, the active layer ACT of each of the pixel transistors PXT and the driver transistors DRT may be formed by forming at least one of the first oxide semiconductor layer OS1 and the second oxide semiconductor layer OS2 at a location where the active layer ACT of each of the pixel transistors PXT and the driver transistors DRT is to be disposed. The active layer ACT of each of the pixel transistors PXT and the driver transistors DRT may be made to be partially conductive in a subsequent process to be divided into the channel region CH, the source region SR, and the drain region DR.

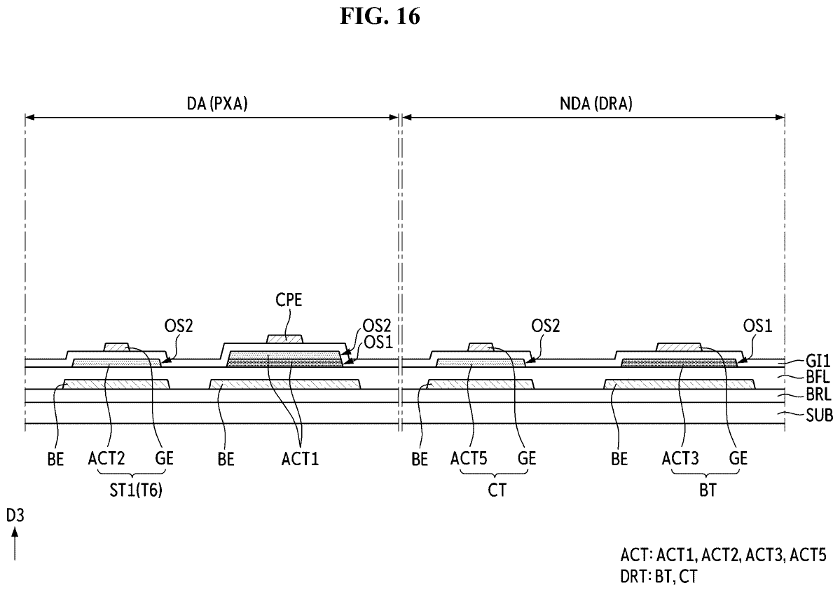

Referring to FIG. 16 in addition to FIGS. 1 to 15, the first gate insulating layer GI1 and at least one gate electrode GE may be formed on the active layers ACT of the pixel transistors PXT and the driver transistors DRT. As an example, the first gate insulating layer GI1 may be formed on the buffer layer BFL and the active layers ACT, and the gate electrodes GE of the first switching transistor ST1, the control transistor CT, and the buffer transistor BT may be then formed on the first gate insulating layer GI1.

When the gate electrode GE of the driver transistor DT is formed directly on the first gate insulating layer GI1 as in an embodiment of FIG. 10, the gate electrodes GE of the first switching transistor ST1, the driver transistor DT, the control transistor CT, and the buffer transistor BT may be formed simultaneously on the first gate insulating layer GI1. When the pixel PX further includes the second switching transistor ST2 as in an embodiment of FIG. 11, the gate electrodes GE of the first switching transistor ST1, the second switching transistor ST2, the control transistor CT, and the buffer transistor BT may be formed simultaneously on the first gate insulating layer GI1. When the pixel PX further includes the capacitor electrode CPE disposed on the first gate insulating layer GI1 as in embodiments of FIGS. 9 and 11, the gate electrodes GE of the first switching transistor ST1, the second switching transistor ST2, the control transistor CT, and/or the buffer transistor BT, and the capacitor electrode CPE may be formed simultaneously on the first gate insulating layer GI1.

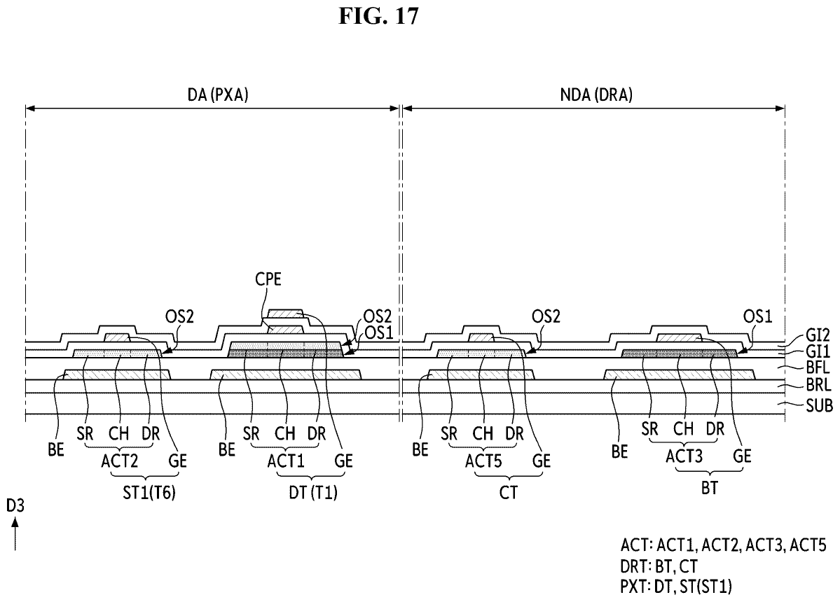

Referring to FIG. 17 in addition to FIGS. 1 to 16, the second gate insulating layer GI2 may be formed on the first gate insulating layer GI1 and the gate electrodes GE and/or the capacitor electrode CPE formed on the first gate insulating layer GI1. When the gate electrode GE of the driving transistor DT is formed on the second gate insulating layer GI2 as in embodiments of FIGS. 6, 9, and 11, the gate electrode GE of the driving transistor DT may be formed on the second gate insulating layer GI2. When the capacitor electrode CPE is formed on the second gate insulating layer GI2 as in an embodiment of FIG. 10, the capacitor electrode CPE may be formed on the second gate insulating layer GI2.

The first gate insulating layer GI1 and the second gate insulating layer GI2 may be formed by a process of forming an insulating film including the insulating material exemplified above. As an example, the first gate insulating layer GI1 may be formed by depositing an inorganic insulating material on the buffer layer BFL and the active layers ACT. In addition, the second gate insulating layer GI2 may be formed by depositing an inorganic insulating material on the first gate insulating layer GI1 and the gate electrodes GE and/or the capacitor electrode CPE formed on the first gate insulating layer GI1. The first gate insulating layer GI1 and the second gate insulating layer GI2 may include the same material or include different materials.

In an embodiment, the first gate insulating layer GI1 and the second gate insulating layer GI2 may be entirely formed on the buffer layer BFL and the active layers ACT. As an example, the first gate insulating layer GI1 and the second gate insulating layer GI2 may be entirely formed in the display area DA and the non-display area NDA (or the driving circuit area DRA).

In another embodiment, the first gate insulating layer GI1 and the second gate insulating layer GI2 may be etched in a shape corresponding to the gate electrodes GE. Accordingly, the first gate insulating layer GI1 and the second gate insulating layer GI2 may cover only a portion (e.g., the channel region CH) of each of the active layers ACT.

In an embodiment, the active layers ACT may have different carrier concentrations for each region by a doping process performed after the gate electrodes GE are formed. Accordingly, each of the active layers ACT may be partitioned into the channel region CH, the source region SR, and the drain region DR. In another embodiment, by etching the first gate insulating layer GI1 and the second gate insulating layer GI2 in the shape corresponding to the gate electrodes GE, carrier concentrations of portions, for example, the source region SR and the drain region DR, of each active layer ACT that are not covered with each gate electrode GE may increase in a process of etching the first gate insulating layer GI1 and the second gate insulating layer GI2 and subsequent processes (e.g., a process of forming the first insulating layer INS1, a heat treatment process, etc.) without performing a separate doping process, such that the channel region CH, the source region SR, and the drain region DR of each of the active layers ACT may be distinguished from each other. A process or a method of partitioning each of the active layers ACT into the channel region CH, the source region SR, and the drain region DR is not limited to the above-described embodiments, and may be changed according to embodiments.

The gate electrodes GE may be formed by a process of forming a conductive film including at least one conductive material and a process of patterning the conductive film. The gate electrodes GE and/or the capacitor electrode CPE formed on the first gate insulating layer GI1 and the gate electrodes GE or the capacitor electrode CPE formed on the second gate insulating layer GI2 may include the same material or include different conductive materials.

By the above-described processes, the pixel transistors PXT may be formed in each pixel area PXA, and the driver transistors DRT may be formed in the driving circuit area DRA.

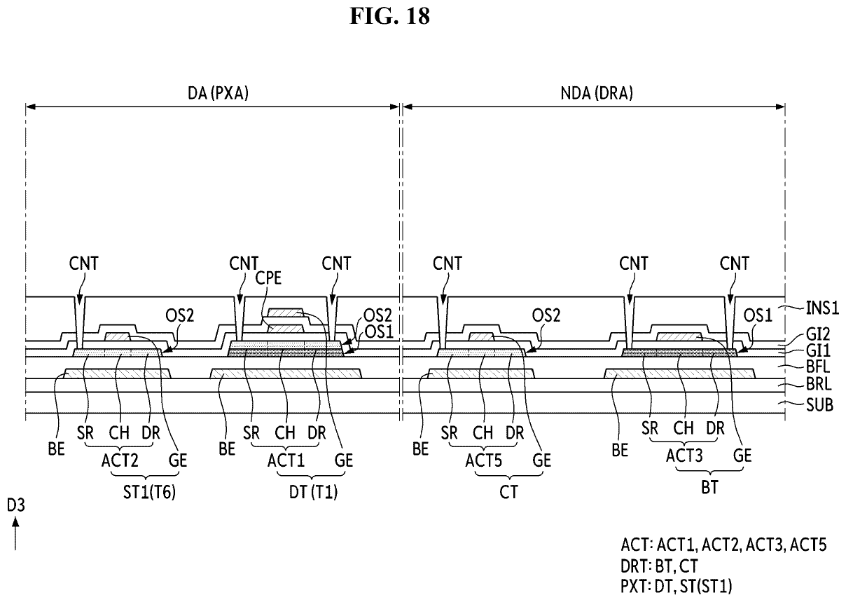

Referring to FIG. 18 in addition to FIGS. 1 to 17, the first insulating layer INS1 covering the pixel transistors PXT and the driver transistors DRT (or the active layers ACT and the gate electrodes GE of the pixel transistors PXT and the driver transistors DRT) may be formed on the second gate insulating layer GI2. The first insulating layer INS1 may be formed by a process of forming an insulating film including at least one insulating material (e.g., an inorganic insulating material).

After the first insulating layer INS1 is formed, contact holes CNT penetrating through the first insulating layer INS1 may be formed. For example, by an etching process using a mask, the contact holes CNT exposing the source region SR and/or the drain region DR of each of at least some pixel transistors PXT and driver transistors DRT may be formed.

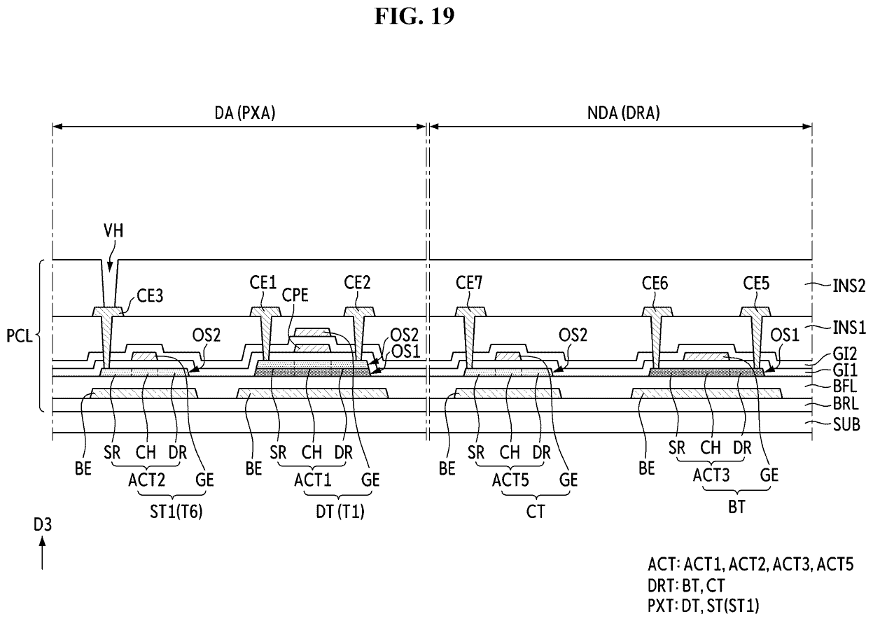

Referring to FIG. 19 in addition to FIGS. 1 to 18, connection electrodes (e.g., the first to seventh connection electrodes CE1 to CE7) filling the respective contact holes CNT may be formed. The connection electrodes may be formed by a process of forming a conductive film including at least one conductive material and a process of patterning the conductive film.

Subsequently, the second insulating layer INS2 covering the connection electrodes may be formed. The second insulating layer INS2 may be formed by a process of forming an insulating film including at least one organic insulating material.

After the second insulating layer INS2 is formed, a via hole VH penetrating through the second insulating layer INS2 may be formed in each pixel area PXA. For example, the via hole VH exposing a portion of the third connection electrode CE3 electrically connected to the sixth transistor T6 of each pixel PX may be formed.

The panel circuit layer PCL may be formed on the substrate SUB by the processes described with reference to FIGS. 13 to 19. The panel circuit layer PCL may include the pixel transistors PXT and the driver transistors DRT according to embodiments.

The pixel transistors PXT according to embodiments may include the driving transistor DT including the first oxide semiconductor layer OS1 and the second oxide semiconductor layer OS2 and the first switching transistor ST1 including the second oxide semiconductor layer OS2. In an embodiment, the pixel transistors PXT may further include the second switching transistor ST2 including the first oxide semiconductor layer OS1. The driver transistors DRT according to embodiments may include the buffer transistor BT including the first oxide semiconductor layer OS1 and the control transistor CT including the second oxide semiconductor layer OS2.

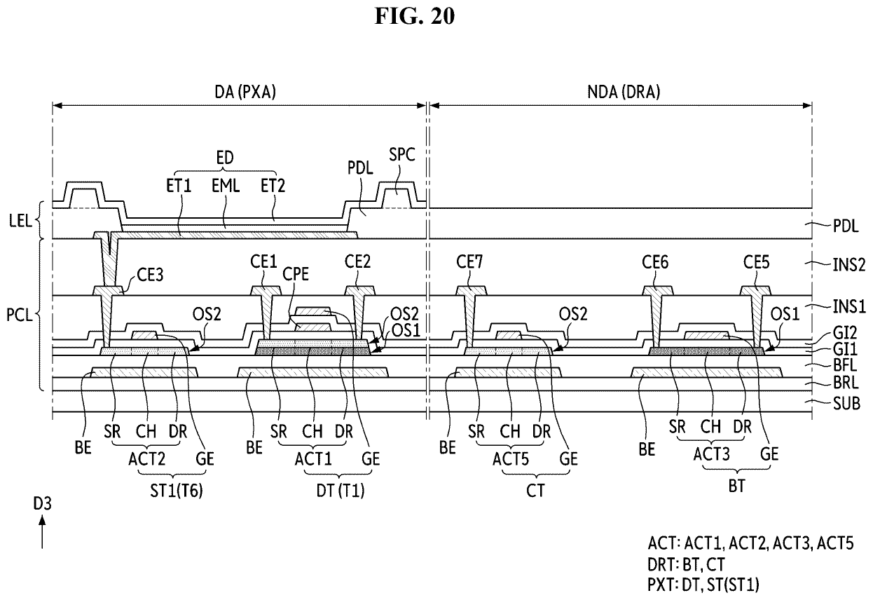

Referring to FIG. 20 in addition to FIGS. 1 to 19, the light emitting element layer LEL may be formed on the panel circuit layer PCL. For example, the first electrode ET1 of the light emitting element ED may be formed on the second insulating layer INS2. The first electrode ET1 of the light emitting element ED may be electrically connected to at least one pixel transistor PXT, for example, the sixth transistor T6, through the via hole VH. Subsequently, the pixel defining layer PDL, the spacer SPC, the light emitting layer EML of the light emitting element ED, and the second electrode ET2 of the light emitting element ED may be sequentially formed on the second insulating layer INS2 and the first electrode ET1 of the light emitting element ED. Accordingly, the light emitting element layer LEL including the light emitting element ED may be formed. In an embodiment, the pixel defining layer PDL may also be formed in at least a portion of the non-display area NDA including the driving circuit area DRA, but is not limited thereto.

Through the above-described processes, the panel circuit layer PCL and the light emitting element layer LEL of the display panel 110 according to an embodiment may be formed. When the display panel 110 includes the encapsulation layer ENL as in embodiments of FIG. 6 and FIGS. 9 to 12, the encapsulation layer ENL may be formed on the light emitting element layer LEL. For example, the first encapsulation layer ENL1, the second encapsulation layer ENL2, and the third encapsulation layer ENL3 may be sequentially formed on the second electrode ET2 of the light emitting element ED (or an inorganic capping layer covering the light emitting element ED). Through the above-described processes, the display panel 110 according to embodiments and the display device 100 including the same may be manufactured.

The display device 100 according to at least one of the above-described embodiments may be applied to various electronic devices. An electronic device according to an embodiment may include the display device 100 described above (or a display module including the display panel 110 according to at least one embodiment), and may further include a module or a device having other additional functions in addition to the display device 100.

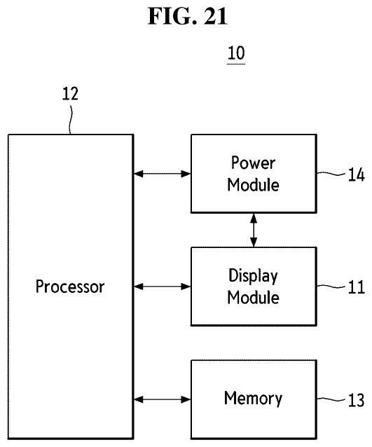

FIG. 21 is a block diagram of an electronic device according to an embodiment.

Referring to FIG. 21, an electronic device 10 according to an embodiment may include a display module 11, a processor 12, a memory 13, and a power module 14.

The electronic device 10 may output various information in the form of an image through the display module 11. For example, when the processor 12 executes an application stored in the memory 13, image information provided by the application may be provided to a user through the display module 11.

The display module 11 may include the display panel 110 for displaying an image. As an example, the display module 11 may include the display panel 110 according to at least one of the above-described embodiments.

The processor 12 may include at least one of a central processing unit (CPU), an application processor (AP), a graphic processing unit (GPU), a communication processor (CP), an image signal processor (ISP), and a controller.

The memory 13 may store data information required for an operation of the processor 12 or the display module 11. For example, the memory 13 may store an image data signal and/or an input control signal.

The processor 12 may control the display module 11 using the information stored in the memory 13. The processor 12 may transmit the image data signal and/or the input control signal stored in the memory 13 to the display module 11. For example, when the processor 12 executes an application stored in the memory 13, the image data signal and/or the input control signal may be transmitted to the display module 11, and the display module 11 may process the received signal and output image information through a display screen.

The power module 14 may include a power supply module such as a power adapter or a battery device and a power conversion module converting power supplied by the power supply module to generate power required for an operation of the electronic device 10.

At least one of the respective components of the above-described electronic device 10 may be included in the display device 100 according to the above-described embodiments. In addition, some of the individual modules functionally included in one module may be included in the display device 100, and the others of the individual modules may be provided separately from the display device 100. For example, the display device 100 may include the display module 11, and the processor 12, the memory 13, and the power module 14 may be provided in the form of other devices within the electronic device 10 rather than the display device 100.

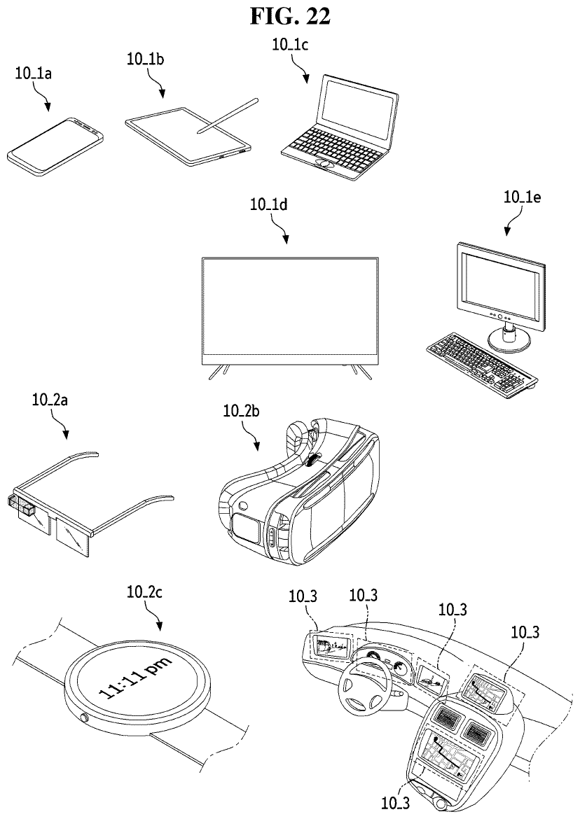

FIG. 22 is schematic views of electronic devices according to various embodiments.

Referring to FIG. 22, various electronic devices to which the display device 100 according to embodiments is applied may include not only image display electronic devices such as a smartphone 10_1a, a tablet PC 10_1b, a laptop computer 10_1c, a television (TV) 10_1d, and a monitor 10_1e for a desktop computer, but also wearable electronic devices including display modules, such as a smart glasses 10_2a, a head mounted display 10_2b, and a smart watch 10_2c, and vehicle electronic devices 10_3 including display modules, such as a center information display (CID) disposed on an instrument board, a center fascia, or a dashboard of a vehicle and a room mirror display.

As described above, the pixel transistors PXT according to embodiments may include the respective active layers ACT differentiated and/or optimized according to operation characteristics required for each pixel transistor PXT. As an example, the driving transistor DT included in the pixel PX may include the first active layer ACT1 including the first oxide semiconductor layer OS1 having the high mobility and the second oxide semiconductor layer OS2 having the low mobility, and at least one first switching transistor ST1 included in the pixel PX may include the second active layer ACT2 including the second oxide semiconductor layer OS2 having the low mobility. In an embodiment, the pixel PX may further include the second switching transistor ST2, and the second switching transistor ST2 may include the fourth active layer ACT4 including the first oxide semiconductor layer OS1 having the high mobility.

In addition, the driver transistors DRT according to embodiments may include the respective active layers ACT differentiated and/or optimized according to operation characteristics required for each driving transistor DRT. As an example, at least one buffer transistor BT included in the first driving circuit 120 may include the third active layer ACT3 including the first oxide semiconductor layer OS1 having the high mobility, and at least one control transistor CT included in the first driving circuit 120 may include the fifth active layer ACT5 including the second oxide semiconductor layer OS2 having the low mobility.

In embodiments, the first oxide semiconductor layer OS1 may include the crystalline oxide semiconductor. Accordingly, it is possible to prevent the first oxide semiconductor layer OS1 from being damaged or removed in a process of manufacturing the display panel 110 and stably and easily form the pixel transistors PXT and the driver transistors DRT.

With the display device 100 and the electronic device 10 including the pixel transistors PXT and the driver transistors DRT according to embodiments, and the method for manufacturing the display device 100, image quality of the display device 100 and the electronic device 10 may be improved, and power consumption of the display device 100 and the electronic device 10 may be reduced. In addition, an area occupied by the non-display area NDA in the display panel 110 of the display device 100 and the electronic device 10 may be reduced.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

In concluding the detailed description, those skilled in the art will appreciate that many variations and modifications can be made to example embodiments without substantially departing from the principles of the present disclosure. Therefore, the disclosed embodiments are to be used in a generic and descriptive sense only and not for purposes of limitation.

What is claimed is:

1. A display device comprising:
a substrate;
a pixel on the substrate,
the pixel including a driving transistor and a first switching transistor,
the driving transistor including a first active layer,
the first active layer including a first oxide semiconductor layer and a second oxide semiconductor layer on the first oxide semiconductor layer,
the first oxide semiconductor layer including a first oxide semiconductor, the second oxide semiconductor layer including a second oxide semiconductor, and the first switching transistor including a second active layer including the second oxide semiconductor; and
a driving circuit on the substrate and including a buffer transistor, the buffer transistor including a third active layer including the first oxide semiconductor, wherein
the first oxide semiconductor includes a crystalline oxide semiconductor.

2. The display device of claim 1, wherein
the pixel further includes a second switching transistor,
the second switching transistor is electrically connected between a first power line and the driving transistor,
the first power line is configured to have a first driving voltage applied thereto,
the second switching transistor includes a fourth active layer, and
the fourth active layer includes the first oxide semiconductor.

3. The display device of claim 1, wherein
the driving circuit further includes a control circuit, in response to an input signal, the control circuit is configured to control a voltage level of a node connected to a gate electrode of the buffer transistor,
the control circuit includes a control transistor,
the control transistor includes a fifth active layer, and
the fifth active layer includes the second oxide semiconductor.

4. The display device of claim 1, wherein a mobility of the first oxide semiconductor is higher than a mobility of the second oxide semiconductor.

5. The display device of claim 1, wherein the second oxide semiconductor includes an amorphous oxide semiconductor.

6. The display device of claim 5, wherein
the first oxide semiconductor includes crystalline indium gallium oxide, and
the second oxide semiconductor includes amorphous indium gallium zinc oxide.

7. The display device of claim 1, wherein a thickness of the first oxide semiconductor layer is ⅓ to ½ of a thickness of the first active layer.

8. The display device of claim 1, wherein
a thickness of the first oxide semiconductor layer is 100 Å to 150 Å, and
a thickness of the second oxide semiconductor layer is 150 Å to 200 Å.

9. The display device of claim 1, further comprising:
a first gate insulating layer on the first active layer, the second active layer, and the third active layer, wherein
a gate electrode of the first switching transistor is on the first gate insulating layer and overlaps a portion of the second active layer.

10. The display device of claim 9, further comprising:
a second gate insulating layer on the first gate insulating layer and the gate electrode of the first switching transistor, wherein
a gate electrode of the driving transistor is on the second gate insulating layer and overlaps a portion of the first active layer.

11. The display device of claim 10, further comprising: a capacitor electrode between the first gate insulating layer and the second gate insulating layer.

12. The display device of claim 9, wherein a gate electrode of the driving transistor is on the first gate insulating layer and overlaps a portion of the first active layer.

13. The display device of claim 12, further comprising:
a second gate insulating layer on the gate electrode of the first switching transistor, the gate electrode of the driving transistor, and the first gate insulating layer; and
a capacitor electrode on the second gate insulating layer.

14. The display device of claim 9, wherein a gate electrode of the buffer transistor is on the first gate insulating layer and overlaps a portion of the third active layer.

15. An electronic device comprising:
a display module including a display panel; and
a processor configured to transmit an image data signal to the display module, wherein
the display panel includes a substrate, a pixel on the substrate, and a driving circuit on the substrate, the pixel includes a driving transistor and a first switching transistor, the driving transistor including a first active layer, the first active layer includes a first oxide semiconductor layer and a second oxide semiconductor layer on the first oxide semiconductor layer,
the first oxide semiconductor layer includes a first oxide semiconductor,
the second oxide semiconductor layer includes a second oxide semiconductor,
the first switching transistor includes a second active layer including the second oxide semiconductor,
the driving circuit includes a buffer transistor,
the buffer transistor includes a third active layer including the first oxide semiconductor, and
the first oxide semiconductor includes a crystalline oxide semiconductor.

16. The electronic device of claim 15, wherein
the pixel further includes a second switching transistor,
the second switching transistor is electrically connected between a first power line and the driving transistor, the first power line is configured to have a first driving voltage applied thereto,
the second switching transistor includes a fourth active layer, and
the fourth active layer includes the first oxide semiconductor.

17. The electronic device of claim 15, wherein
the driving circuit further includes a control circuit, in response to an input signal, the control circuit is configured to control a voltage level of a node connected to a gate electrode of the buffer transistor,
the control circuit includes a control transistor,
the control transistor includes a fifth active layer, and
the fifth active layer includes the second oxide semiconductor.

18. A method for manufacturing a display device, comprising:
forming a first oxide semiconductor layer on a substrate;
forming a second oxide semiconductor layer on the first oxide semiconductor layer to form a first active layer including the first oxide semiconductor layer and the second oxide semiconductor layer;
forming a first gate insulating layer on the substrate and the first active layer; and
forming a gate electrode of a driving transistor on the first gate insulating layer, wherein the driving transistor includes the first active layer, the gate electrode of the driving transistor overlaps the first active layer, wherein
the forming the first oxide semiconductor layer includes forming a first semiconductor pattern on the substrate and crystallizing the first semiconductor pattern, and
the first semiconductor pattern including an amorphous oxide semiconductor.

19. The method of claim 18, wherein
in the forming the first oxide semiconductor layer, a third active layer including a same material as the first oxide semiconductor layer is further formed, and
in the forming the second oxide semiconductor layer, a second active layer including a same material as the second oxide semiconductor layer is further formed.

20. The method of claim 19, further comprising:
forming a switching transistor and a buffer transistor by forming a gate electrode of the switching transistor and a gate electrode of the buffer transistor on the first gate insulating layer, the switching transistor includes the second active layer and the gate electrode of the switching transistor is formed above the second active layer so as to overlap the second active layer,
the buffer transistor includes the third active layer and the gate electrode of the buffer transistor is formed above the third active layer so as to overlap the third active layer.
